(19) United States
(12) Patent Application Publication
(10) Pub. No.: US 2011/0176568 A1
(43) Pub. Date: Jul. 21, 2011

(54) NITRIDE SEMICONDUCTOR LASER DIODE

(76) Inventors: Tomoya Satoh, Osaka (JP); Tatsuya Nakamori, Okayama (JP); Takahiro Okaguchi, Hyogo (JP); Toru Takayama, Hyogo (JP); Yoshiaki Hasegawa, Okayama (JP)

(21) Appl. No.: 12/948,152

(22) Filed: Nov. 17, 2010

(30) Foreign Application Priority Data
Jan. 20, 2010 (JP) 2010-010389
Apr. 20, 2010 (JP) 2010-097087
Sep. 10, 2010 (JP) 2010-202786

(51) Int. Cl. H01S 5/02

(52) U.S. Cl. 372/44.01

(57) ABSTRACT

A nitride semiconductor laser diode includes a second conductive cladding layer formed on an active layer, and including a ridge portion having a raised cross-sectional shape, and flat portions located on both sides of the ridge portion; a light-absorbing layer formed on each of the flat portions, and having an optical absorption coefficient larger than the second conductive cladding layer. The light-absorbing layer includes a first region provided at a side of a light-emitting facet, and having a distance Di1 from a line-symmetric axis in a longitudinal direction of the ridge portion to a side surface of the light-absorbing layer; and a second region provided at a side opposite to the light-emitting facet, and having a distance Di2 from the line-symmetric axis to the side surface of the light-absorbing layer. A relationship between the Di1 and the Di2 is represented by Di1<Di2.

### CROSS-REFERENCE TO RELATED APPLICATION

This application claims priority to Japanese Patent Application No. 2010-10389 filed on Jan. 20, 2010, Japanese Patent Application No. 2010-97087 filed on Apr. 20, 2010, and Japanese Patent Application No. 2010-202786 filed on Sep. 10, 2010, the disclosures of which including the specifications, the drawings, and the claims are hereby incorporated by reference in their entirety.

### BACKGROUND

The present disclosure relates to nitride semiconductor laser diodes emitting laser light by laser oscillation.

In recent years, DVD systems for Blu-ray Discs (registered trademark) have been widely used, which record high definition (HD) video data of digital terrestrial broadcasting on digital versatile disks (DVDs) for a long period. In accordance with the spread of the DVD systems for Blu-ray Discs, an improvement in quality and a decrease in costs of nitride semiconductor laser diodes having light sources with a wavelength of 405 nm band have been strongly demanded by the market.

In nitride semiconductor laser diodes for optical disks such as Blu-ray Discs, characteristics of far field pattern (FFP), which is a radiation angle of emitted beam, need to be stable to increase optical output and stabilize reading and writing of the data so that the speed of recording data onto the optical disks is increased (see, e.g., U.S. Pat. No. 4,045,792 and International Patent Publication 2009/066428 pamphlet).

Specifically, recent nitride semiconductor laser diodes for Blu-ray Discs have been required to have optical output of 300 mW or more and FFP characteristics of 8° in the horizontal direction and 18° in the vertical direction, and to stably operate even in a high-output state.

FIG. 23 illustrates a cross-sectional structure of a conventional nitride semiconductor laser diode 200.

As shown in FIG. 23, the conventional nitride semiconductor laser diode 200 includes a cladding layer 102 made of n-type aluminum gallium nitride (AlGaN), an active layer 104, a cladding layer 106 made of p-type AlGaN including a ridge portion 106a and flat portions 106b on the both sides of the ridge portion 106a, a contact layer 107 made of p-type gallium nitride (GaN), an insulating film 108 confining a current and light, a p-side electrode 109 being in ohmic-contact with the contact layer 107; which are sequentially formed on a substrate 101 made of n-type GaN; and an n-side electrode 110 bonded to the back surface of the substrate 101. The active layer 104 includes a guide layer 104a made of n-type AlGaN, an active layer 104b made of indium gallium nitride (InGaN), and an electron blocking layer 104c made of p-type AlGaN. The insulating film 108 is made of a dielectric material having a smaller refractive index than the cladding layer 106 to confine light.

FIG. 24 is a cross-sectional view of the nitride semiconductor laser diode 200 taken along the line XXIV-XXIV of FIG. 23, and illustrates a cross-sectional structure taken in the direction perpendicular to the y-axis direction. In the nitride semiconductor laser diode 200, L denotes the cavity length in the cavity length direction (the direction parallel to the emitting direction of laser light) parallel to the z-axis direction in FIG. 23 when seen from the y-axis direction. The cross-sectional structure in FIG. 23 has a uniform structure from a front facet 115, which is a light-emitting facet of laser light, to a rear facet 116.

Conventionally, when the nitride semiconductor laser diode 200 is in a high-output state, a phenomenon called “kinks” easily occurs, which is deterioration of linearity of optical output with respect to an injected current. This makes it difficult to obtain stable optical output characteristics. The cause of kinks is that the ridge portion 106a of the cladding layer 106 generates heat by light absorption and Joule heat in accordance with an increase in optical output in the nitride semiconductor laser diode 200. This may increase the refractive index of the cladding layer 106 to improve the optical confinement capabilities of the cladding layer 106.

FIGS. 25A and 25B illustrate cross-sectional structure of the nitride semiconductor laser diode 200 shown in FIGS. 23 and 24, and are schematic diagrams converted to one-dimensional refractive index distribution based on approximation by effective refractive indexes in low output and high output of laser light. As shown in FIG. 25A, an effective refractive index difference ΔN_{low}, which is the difference in the effective refractive index between the ridge portion 106a and the flat portions 106b on the both sides of the ridge portion 106a in low output, is set to satisfy the condition for a single transverse mode in which only a fundamental transverse mode can exist in the nitride semiconductor laser diode 200.

On the other hand, as shown in FIG. 25B, an effective refractive index difference ΔN_{high} between the ridge portion 106a and the flat portions 106b in high output does not satisfy the condition for the single transverse mode in accordance with an increase in optical output, since the refractive index of the ridge portion 106a rises due to heat generation and the like. As a result, a higher-order transverse mode easily occurs. Thus, interference between the fundamental transverse mode and the higher-order transverse mode occurs in the nitride semiconductor laser diode 200 in accordance with the increase in the output. As a result, laser light becomes unstable to easily cause kinks.

Therefore, in order to increase the optical output causing the kinks (hereinafter referred to as “kink level”), the single mode condition of the nitride semiconductor laser diode 200 needs to be reinforced not to cause the interference between the fundamental transverse mode and the higher-order transverse mode.

As a basic remedy for reinforcing the single mode condition, as shown in FIG. 23, the thickness d of the flat portions 106b of the cladding layer 106 in the nitride semiconductor laser diode 200 is increased, thereby reducing the effective refractive index difference ΔN and degrading optical confinement capabilities in the horizontal direction. Also, the method of reducing the occurrence of the higher-order transverse mode by reducing the ridge width W of the ridge portion 106a is used.

However, raising the kink level by controlling the thickness d of the flat portions 106b in the cladding layer 106 and the ridge width W reduces, in an opposite manner, the effective refractive index difference ΔN to degrade optical confinement capabilities in the horizontal direction, resulting in narrowing of the horizontal FFP.

Furthermore, the shape of the FFP in the semiconductor laser diode 200 for optical disks such as Blu-ray Discs, needs to be a stable Gaussian shape to write and read data to and from the optical disks. In the nitride semiconductor laser diode 200 shown in FIGS. 23 and 24, the substrate 101 made of n-type GaN, the cladding layer 102 made of n-type AlGaN, and the cladding layer 106 made of p-type AlGaN are transparent to light with a wavelength of 405 nm band. Thus, scattered light generated in asperities at the boundary between the substrate 101 and the cladding layer 102, and scattered light etc. caused by asperities of the interface between the cladding layer 106 and the insulating film 108 cause ripples in the horizontal FFP and the vertical FFP to distort the waveform. As a result, the FFP shape differs from the Gaussian shape. Also, when the FFP waveform is distorted by the ripples, the FFP tends to be narrow, and thus, such a diode is not preferable as a light source for optical disks.

In order to improve the distortion of the FFP waveform, the method of reducing the influence of the scattered light by increasing the thickness of the active layer 104 or increasing the ridge width W is considered. However, this method leads to lowering of the kink level and narrowing of the horizontal FFP to make it difficult to realize a nitride semiconductor laser diode required as a light source for Blu-ray Discs.

Each of U.S. Pat. No. 4,045,792 and International Patent Publication 2009/066428 pamphlet shows as a nitride semiconductor laser diode, the structure in which an insulating film or a light absorbing body, which is spaced apart from a ridge portion and having a high refractive index, is provided on the both sides of the ridge portion to reduce ripples of the FFP. In this structure, light leaking outside the ridge portion, which causes ripples of the FFP, is guided by a dielectric film (insulating film) having a high refractive index, thereby reducing the ripples of the FFP of fundamental transverse mode light.

### SUMMARY

However, in the structures of the above U.S. Pat. No. 4,045,792 and International Patent Publication 2009/066428 pamphlet, the ripples of the FFP in nitride semiconductor laser diode having optical output of about tens mW are reduced. Thus, in order to realize a nitride semiconductor laser diode having an optical output of 300 mW or more, which is required as recording speed of eight times or more in Blu-ray Discs, the thickness d of the flat portions 106b in the cladding layer 106, and the ridge width W need to be adjusted so that the effective refractive index difference ΔN is reduced and the characteristics of the single transverse mode are reinforced.

As such, in the methods shown in U.S. Pat. No. 4,045,792 and International Patent Publication 2009/066428 pamphlet, when output of the semiconductor laser diode is increased, the horizontal FFP is narrowed, and this makes it difficult to realize a high-output nitride semiconductor laser diode for Blu-ray Discs.

Each of Japanese Translation of PCT International Application No. 2002-500447 and Japanese Patent Publication No. 2006-269954 teaches providing a light-absorbing layer (kink blocking layer/buried absorption layer), which absorbs light with an oscillation wavelength, on the sides of a ridge portion to improve the kink level without degrading the optical confinement capabilities in the horizontal direction. This structure absorbs the higher-order transverse mode light, which is considered as a cause of kinks, thereby improving the kink level.

However, in the structure shown in Japanese Translation of PCT International Application No. 2002-500447, the thickness of the light-absorbing layer is formed relatively thick, ranging from 50 nm to 100 nm. This makes it difficult for the higher-order transverse mode light to spreading to the light-absorbing layer, and thus, little light is absorbed. Therefore, the advantage of improving the kink level cannot be provided as much as expected. Furthermore, since the light-absorbing layer with a large thickness is formed between a cladding layer and an insulating film, disconnection caused by a step may occur in the insulating film, thereby increasing leakage current to damage the reliability of the semiconductor laser diode.

In the semiconductor laser diode shown in Japanese Patent Publication No. 2006-269954, a light-absorbing layer with a thickness of 0.001 μm or more is formed within a range of 0.5 μm from the side surface of a ridge portion. Thus, fundamental mode light is largely absorbed to largely reduce the threshold current and current-light conversion efficiency (hereinafter referred to as “slope efficiency”).

In order to solve the above problems, it is an objective of the present disclosure to realize a nitride semiconductor laser diode with stable far field pattern (FFP) characteristics and a wider angle, even when output power of laser light is increased.

In order to achieve the objective, in a nitride semiconductor laser diode of the present disclosure, a distance between a light-absorbing layer and a side surface of a ridge portion at the side of a light-emitting facet is smaller than that at the opposite side to the light-emitting facet, or a thickness of the light-absorbing layer at the side of the light-emitting facet is larger than that at the opposite side.

Specifically, a first nitride semiconductor laser diode according to the present disclosure includes a first conductive cladding layer formed on a substrate; an active layer formed on the first conductive cladding layer; a second conductive cladding layer formed on the active layer, and including a ridge portion extending in an emitting direction of light and having a raised cross-sectional shape, and flat portions located on both sides of the ridge portion; a light-absorbing layer formed on each of the flat portions, and having an optical absorption coefficient larger than the second conductive cladding layer with respect to an oscillation wavelength; and an insulating film formed on side surfaces of the flat portions and the ridge portion of the second conductive cladding layer including the light-absorbing layer. The light-absorbing layer includes a first region provided at a side of a light-emitting facet, and having a distance Di1 from a center of the ridge portion, which is a line-symmetric axis in a longitudinal direction of the ridge portion, to a side surface of the light-absorbing layer at a side of the ridge portion, and a second region provided at a side opposite to the light-emitting facet to be continuous with or spaced apart from the first region, and having a distance Di2 from the center of the ridge portion to the side surface of the light-absorbing layer at the side of the ridge portion. A relationship between the Di1 and Di2 is represented by Di1<Di2.

According to the first nitride semiconductor laser diode, the distance from the center of the ridge portion to the side surface of the light-absorbing layer at the side of the ridge portion in the first region is smaller than that in the second region. Thus, fundamental transverse mode light in the first region and fundamental transverse mode light in the second region interfere with each other due to the mode mismatch at the boundary between the first region and the second region. The component of this mode mismatch is radiated outside the ridge portion in the radiation mode, and is absorbed by the light-absorbing layer. This allows the horizontal FFP in a stationary state to converge to a predetermined value while oscillating. Thus, even when the output of laser light is increased, the value of the horizontal FFP in the first region can be larger than the value of the horizontal FFP in the second region to increase the angle of the horizontal FFP in the first region by actively utilizing the interference between the fundamental transverse mode light in the first region and the second region. This realizes a nitride semiconductor laser diode with a stable radiation angle of emitted beam, i.e., stable far field pattern (FFP) characteristics.

In the first nitride semiconductor laser diode, the distance Di1 may continuously change to the distance Di2 in the second region.

In the first nitride semiconductor laser diode, the light-absorbing layer may absorb laser light having a beam radius out of a predetermined range of size in the first region.

In the first nitride semiconductor laser diode, the second conductive cladding layer may have a thickness ranging from 10 nm to 70 nm at the flat portions.

In the first nitride semiconductor laser diode, the Di1 may range from 1.0 μm to 2.0 μm.

In the first nitride semiconductor laser diode, the Di2 may be 2.5 μm or more.

In the first nitride semiconductor laser diode, the first region in the light-absorbing layer may have a length ranging from 10 μm to 100 μm in the emitting direction of the light.

In the first nitride semiconductor laser diode, the second region in the light-absorbing layer may have a length of 30 μm or more in the emitting direction of the light.

In the first nitride semiconductor laser diode, the first region in the light-absorbing layer may have a width ranging from 4 μm to 25 μm.

In the first nitride semiconductor laser diode, the first region in the light-absorbing layer may have a thickness ranging from 20 nm to 140 nm.

In the first nitride semiconductor laser diode, where the second region is spaced apart from the first region, the space between the first region and the second region may be 10 μm or less.

A second nitride semiconductor laser diode according to the present disclosure includes a first conductive cladding layer formed on a substrate; an active layer formed on the first conductive cladding layer; a second conductive cladding layer formed on the active layer, and including a ridge portion extending in an emitting direction of light and having a raised cross-sectional shape, and flat portions located on both sides of the ridge portion; and a light-absorbing layer formed above each of the flat portions with a space interposed therebetween, and having an optical absorption coefficient larger than the second conductive cladding layer with respect to an oscillation wavelength; and an insulating film formed on side surfaces of the flat portions and the ridge portion of the second conductive cladding layer including the light-absorbing layer. The light-absorbing layer includes a first region provided at a side of a light-emitting facet and having a thickness D1, and a second region connected to the first region and having a thickness D2. A relationship between the D1 and the D2 is represented by D1<D2.

According to the second nitride semiconductor laser diode, since the percentage of higher-order transverse mode light can be reduced due to the second region in the light-absorbing layer, of which thickness is reduced; the kink level can be improved. Furthermore, the thickness D1 of the first region at the side of the light-emitting side surface of the light-absorbing layer is larger than the thickness D2 of the second region, thereby mitigating reduction in the horizontal FFP. Therefore, the light-absorbing layer which does not affect current-optical output characteristics can be provided to stabilize high-output operation and increase the angle of the horizontal FFP.

In the first or second nitride semiconductor laser diode, the light-absorbing layer may be made of a material absorbing laser light with a wavelength of 405 nm band.

In this case, the light-absorbing layer may be made of silicon or amorphous silicon.

In the second nitride semiconductor laser diode, the light-absorbing layer may have a thickness D2 ranging from 2 nm to 20 nm in the second region.

In the second nitride semiconductor laser diode, the light-absorbing layer may have a thickness D1 ranging from 2 nm to 50 nm in the first region.

In the second nitride semiconductor laser diode, where S1 is a distance in the first region from a center of the ridge portion, which is a line-symmetric axis in a longitudinal direction of the ridge portion, to a side surface of the light-absorbing layer at a side of the ridge portion; and S2 is a distance in the second region from the center of the ridge portion to the side surface of the light-absorbing layer at the side of the ridge portion; a relationship between the S1 and the S2 may be represented by S1≦S2.

In this case, the distance S1 in the first region may be 1.0 μm or more.

Furthermore, in this case, the distance S2 in the second region may range from 1.0 μm to 2.5 μm.

In the second nitride semiconductor laser diode, where L1 is a length of the first region in the light-absorbing layer in the longitudinal direction of the ridge portion, the L1 may range from 20 μm to 150 μm.

In this case, where L2 is a length in a longitudinal direction of the ridge portion of the second region in the light-absorbing layer, a sum of the L1 and L2 may be equal to or less than a length of the ridge portion in the longitudinal direction.

In the second nitride semiconductor laser diode, a width of the ridge portion of the light-absorbing layer in a direction perpendicular to the longitudinal direction may range from 4 μm to 20 μm.

In the first or second nitride semiconductor laser diode, a width of the ridge portion may range from 1.1 μm to 1.7 μm.

In the first or second nitride semiconductor laser diode, the substrate may be made of n-type gallium nitride, the first conductive cladding layer may be made of n-type nitride semiconductor, the second conductive cladding layer may be made of p-type nitride semiconductor, and the active layer may be made of nitride semiconductor.

As described above, according to the nitride semiconductor laser diode of the present disclosure, a nitride semiconductor laser diode with stable far field pattern (FFP) characteristics and a wider angle can be realized, even when output power of laser light is increased.

### BRIEF DESCRIPTION OF THE DRAWINGS

FIG. 1 is a cross-sectional view of a nitride semiconductor laser diode according to a first example embodiment.

FIG. 2 is a cross-sectional view taken along the line II-II of FIG. 1.

FIG. 3 is a table illustrating values of Al composition, In composition, and the thickness of each layer in the nitride semiconductor laser diodes of the first to third embodiments.

FIG. 4A is a graph illustrating a calculation result of the horizontal near field patterns (NFPs) of first and second regions in the nitride semiconductor laser diode according to the first example embodiment.

FIG. 4B is a graph illustrating a calculation result of the horizontal FFPs of the first and second regions in the nitride semiconductor laser diode according to the first example embodiment.

FIG. 4C is a table illustrating a calculation result of the horizontal FFPs of the first and second regions in the nitride semiconductor laser diode according to the first example embodiment.

FIG. 5 is a graph illustrating a calculation result of the horizontal FFP with respect to a length L1 of the first region in a light-absorbing layer in the nitride semiconductor laser diode according to the first example embodiment.

FIG. 6A is a graph illustrating an analysis result of FFPs in the nitride semiconductor laser diode according to the first example embodiment, where the length L1 of the first region in the light-absorbing layer is 0, 20, 40, 60 and 100 μm.

FIG. 6B is a table illustrating an analysis result of FFPs in the nitride semiconductor laser diode according to the first example embodiment, where the length L1 of the first region in the light-absorbing layer is 0, 20, 40, 60 and 100 μm.

FIG. 7A is a graph illustrating optical output-current (L-I) characteristics in the nitride semiconductor laser diode according to the first example embodiment, where the length L1 of the first region in the light-absorbing layer is 0 μm.

FIG. 7B is a graph illustrating optical output-current (L-I) characteristics in the nitride semiconductor laser diode according to the first example embodiment, where the length L1 of the first region in the light-absorbing layer is 40 μm.

FIG. 7C is a table illustrating the threshold current and slope efficiency in the nitride semiconductor laser diode according to the first example embodiment, where the length L1 of the first region in the light-absorbing layer is 0 μm and 40 μm.

FIG. 8A is a graph illustrating FFP characteristics in the nitride semiconductor laser diode according to the first example embodiment, where an output is 5 mW.

FIG. 8B is a graph illustrating the FFP characteristics in the nitride semiconductor laser diode according to the first example embodiment, where the output is 100 mW.

FIG. 8C is a table illustrating the FFP characteristics in the nitride semiconductor laser diode according to the first example embodiment, where the output is 5 mW and 100 mW.

FIG. 9 illustrates a nitride semiconductor laser diode according to a first variation of the first example embodiment, and is a cross-sectional view corresponding to the cross-section taken along the line II-II of FIG. 1.

FIG. 10 illustrates a nitride semiconductor laser diode according to a second variation of the first example embodiment, and is a cross-sectional view corresponding to the cross-section taken along the line II-II of FIG. 1.

FIG. 11 illustrates a nitride semiconductor laser diode according to a third variation of the first example embodiment, and is a cross-sectional view corresponding to the cross-section taken along the line II-II of FIG. 1.

FIG. 12 illustrates a nitride semiconductor laser diode according to a second example embodiment, and is a cross-sectional view corresponding to the cross-section taken along the line II-II of FIG. 1.

FIG. 13 is a graph illustrating a calculation result of a horizontal FFP with respect to a length L1 of a first region in a light-absorbing layer in the nitride semiconductor laser diode according to the second example embodiment.

FIG. 14 is a table illustrating an analysis result of the FFP in the nitride semiconductor laser diode according to the second example embodiment, where the length L1 of the first region in the light-absorbing layer is 0 μm and 40 μm.

FIG. 15 is a cross-sectional view of a nitride semiconductor laser diode according to a third example embodiment.

FIG. 16A is a cross-sectional view taken along the line XVIa-XVIa of FIG. 15. FIG. 16B is a cross-sectional view taken along the line XVIb-XVIb of FIG. 16A.

FIG. 17 is a graph illustrating a calculation result of intensity of higher-order transverse mode light in the nitride semiconductor laser diode according to the third example embodiment, where a thickness of the light-absorbing layer is uniformly changed.

FIG. 18 is a graph illustrating a calculation result of a damage to a waveguide of the higher-order transverse mode light with respect to the thickness of the light-absorbing layer in the nitride semiconductor laser diode according to the third example embodiment.

FIGS. 19A-19C illustrate operating current-optical output characteristics in the nitride semiconductor laser diode according to the third example embodiment. FIG. 19A is a graph illustrating where the thickness of the light-absorbing layer is 5 nm. FIG. 19B is a graph illustrating where the thickness of the light-absorbing layer is 10 nm. FIG. 19C is a graph illustrating where the thickness of the light-absorbing layer is 50 nm.

FIG. 20 is a graph illustrating the relationship between the percentage of the higher-order transverse mode light to fundamental transverse mode light and a kink level in the nitride semiconductor laser diode according to the third example embodiment.

FIG. 21A is a graph illustrating a calculation result of a horizontal NFP waveform in a first region and a second region in the nitride semiconductor laser diode according to the third example embodiment. FIG. 21B is a graph illustrating a calculation result of a horizontal FFP waveform in the first and second regions in the nitride semiconductor laser diode according to the third example embodiment.

FIG. 22 is a graph illustrating a calculation result of the horizontal FFP with respect to the length L1 of the first region in the light-absorbing layer in the nitride semiconductor laser diode according to the third example embodiment.

FIG. 23 is a cross-sectional view of a conventional nitride semiconductor laser diode.

FIG. 24 is a cross-sectional view taken along the line XXIV-XXIV of FIG. 23.

FIG. 25A is a schematic diagram in which the cross-sectional structure of the conventional nitride semiconductor laser diode in low output is converted to one-dimensional refractive index distribution based on an approximate effective refractive index.

FIG. 25B is a schematic diagram in which the cross-sectional structure of the conventional nitride semiconductor laser diode in high output is converted to one-dimensional refractive index distribution based on the approximate effective refractive index.

### DETAILED DESCRIPTION

### First Example Embodiment

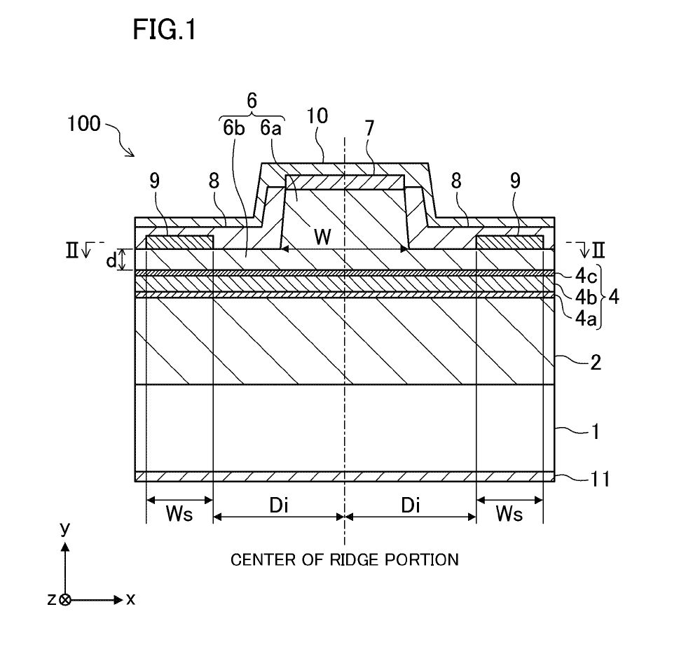

A nitride semiconductor laser diode according to a first example embodiment will be described hereinafter with reference to FIGS. 1-8C. In the present disclosure, configurations shown in the following embodiments, their variations, and the attached drawings are merely examples; and the present disclosure is not limited thereto.

A nitride semiconductor laser diode 100 according to the first example embodiment has a cavity structure extending in an emitting direction of laser light, and laser light with an oscillation wavelength of 405 nm band is output by laser oscillation.

Specifically, the laser diode includes an n-type cladding layer formed on a substrate made of n-type gallium nitride (GaN); an active layer formed on the n-type cladding layer, and having a quantum well structure; an optical guide layer formed under the active layer, and guiding laser light generated in the active layer; an overflow barrier layer formed on the active layer, and blocking overflow of carriers injected into the active layer; a p-type cladding layer formed on the overflow barrier layer, and having a raised ridge portion extending in a longitudinal direction of the cavity (the emitting direction of laser light) and flat portions provided on both sides of the ridge portion; a light-absorbing layer formed on each of the flat portions on the both sides of the ridge portion to be spaced apart from the ridge portion, and having an optical absorption coefficient larger than the p-type cladding layer with respect to an oscillation wavelength; and an insulating film formed on the p-type cladding layer and the light-absorbing layer.

The light-absorbing layer is provided near an emitting facet of laser light. The light-absorbing layer includes a first region, in which Di1 is the distance from the center of the ridge portion, which is parallel to the emitting direction of laser light and is a line-symmetric axis of the ridge portion, to the side surface of the light-absorbing layer at the side of the ridge portion. The light-absorbing layer also includes a second region provided to be continuous with or spaced apart from the first region. In the second region, Di2 is the distance from the center of the ridge portion to the side surface of the light-absorbing layer at the side of the ridge portion. The relationship between the distance Di1 in the first region and the distance Di2 in the second region is represented by Di1<Di2. This configuration realizes the nitride semiconductor laser diode 100 with a stable radiation angle of emitted beam of laser light to enable wide-angle operation even the output of laser light is increased.

An example of the nitride semiconductor laser diode 100 according to the first example embodiment will be described below with reference to FIG. 1.

As shown in FIG. 1, the nitride semiconductor laser diode 100 according to the first example embodiment includes an n-type cladding layer 2 made of n-type AlₓGa₁₋ₓN, an active layer 4, a p-type cladding layer 6 made of p-type AlₓGa₁₋ₓN, and a p-type contact layer 7 made of p-type GaN; which are sequentially formed by epitaxial growth on an n-type substrate 1 made of n-type GaN; where x represents the aluminum (Al) composition, and y represents the indium (In) composition.

The p-type cladding layer 6 includes a ridge portion 6a in a raised cross-sectional shape (mesa shape), which extends in the emitting direction of laser light and including a cavity, and flat portions 6b which are continuously formed to both sides of the ridge portion 6a. A light-absorbing layer 9, which is spaced apart from each of the both side surfaces of the ridge portion 6a and absorb laser light with an oscillation wavelength band, is formed on each of the both flat portions 6b in the p-type cladding layer 6. Also, an insulating film 8, which covers the light-absorbing layer 9 and is made of a dielectric material having the functions of current and optical confinement, is formed on the both side surfaces of the ridge portion 6a and on the both flat portions 6b in the p-type cladding layer 6.

In FIG. 1, Di denotes the distance from the center of the ridge portion to the side surface of the light-absorbing layer 9 at the side of the ridge portion 6a. Reference character d denotes the thickness of the flat portions 6b in the p-type cladding layer 6, and Ws denotes the width of the light-absorbing layer 9.

The p-type contact layer 7 is formed on the top surface of the ridge portion 6a of the p-type cladding layer 6, i.e., in an exposed portion from the insulating film 8. A p-side electrode 10, which is in ohmic contact with the p-type contact layer 7, is formed on the insulating film 8 and the p-type contact layer 7. An n-side electrode 11, which is in ohmic contact with the n-type substrate 1, is formed on the surface (back surface) of the n-type substrate 1 opposite to the n-type cladding layer 2.

The active layer 4 includes an n-type guide layer 4a made of n-type AlₓGa₁₋ₓN, an active layer 4b made of In_{y}Ga_{1-y}N and having a quantum well structure including a well layer and barrier layers, and a p-type electron blocking layer 4c made of p-type AlₓGa₁₋ₓN and blocking overflow of electrons (carriers) from the active layer 4b. Note that in the first example embodiment and other example embodiments, x and y denoting the Al composition and the In composition may be omitted to that AlₓGa₁₋ₓN is represented by AlGaN and In_{y}Ga_{1-y}N is represented by InGaN.

The outline of a manufacturing method of the nitride semiconductor laser diode 100 configured as above will be described below.

First, the layers from the n-type cladding layer 2 to the p-type contact layer 7 are sequentially formed on the n-type substrate 1 by crystal growth using for example, metal organic chemical vapor deposition (MOCVD).

Then, the ridge portion 6a in a mesa shape for injecting currents into the active layer 4b and confining light is selectively formed in the p-type cladding layer 6 by lithography and dry etching such as reactive ion etching. At this time, in order to satisfy the oscillation condition of a single transverse mode at or near the oscillation threshold current value of laser light, dry etching is performed with the ridge portion 6a in the p-type cladding layer 6 having a ridge width W of 1.4 μm, and the flat portions 6b having a thickness d of 50 nm. As shown in FIG. 1, the ridge width W denotes the width of the ridge portion 6a at the boundary between the ridge portion 6a and the flat portions 6b, i.e., the width of the bottom of the ridge portion 6a having a raised cross-sectional shape.

Next, a semiconductor film for forming the light-absorbing layer is deposited over the entire surface of the p-type cladding layer 6 by vacuum vapor deposition etc. After that, the deposited semiconductor film is patterned so that each of the inner side surfaces is spaced apart from the center of the ridge portion with a distance Di on each of the flat portions 6b by lithography and dry etching to form the light-absorbing layer 9 from the semiconductor film. The semiconductor film forming the light-absorbing layer 9 can be made of a semiconductor material such as amorphous silicon (α-Si) or silicon (Si) absorbing light with a wavelength of 405 nm which is the oscillation wavelength of the nitride semiconductor laser diode 100. In order to increase the angle of the horizontal FFP, the thickness of the light-absorbing layer 9 is set to about 50 nm. Furthermore, one of the features of the first example embodiment is that the distance Di1 between the light-absorbing layer 9 and the ridge portion 6a at the side of the light-emitting facet is smaller than the distance Di2 between the light-absorbing layer 9 and the ridge portion 6a in other regions. This increases the angle of horizontal FFP as described below.

Then, the insulating film 8, which is made of a dielectric material such as silicon dioxide (SiO₂), silicon nitride (SiN), tantalum oxide (Ta₂O₅) or zirconium dioxide (ZrO₂), is deposited by CVD etc. over the entire surface of the p-type cladding layer 6 including the light-absorbing layer 9. After that, the insulating film 8 in an upper portion of the ridge portion 6a of the p-type cladding layer 6 is selectively removed by lithography and dry etching to expose the top surface of the ridge portion 6a.

Next, the p-side electrode 10 made of a metal multilayer film of, e.g., titanium (Ti)/platinum (Pt)/gold (Au) is formed on the insulating film 8 and the top surface of the ridge portion 6a exposed from the insulating film 8 by sputtering, vacuum vapor deposition, or the like. The formed p-side electrode 10 comes into ohmic contact with the p-type contact layer 7.

After that, the n-side electrode 11 made of a metal multilayer film of, e.g., titanium (Ti)/platinum (Pt)/gold (Au) is formed on the back surface of the n-type substrate 1 by sputtering, vacuum vapor deposition, or the like. The formed n-side electrode 11 comes into ohmic contact with the n-type substrate 1.

Note that in the nitride semiconductor laser diode 100 according to the first example embodiment, the insulating film 8 is made of silicon dioxide, and the light-absorbing layer 9 is made of α-Si.

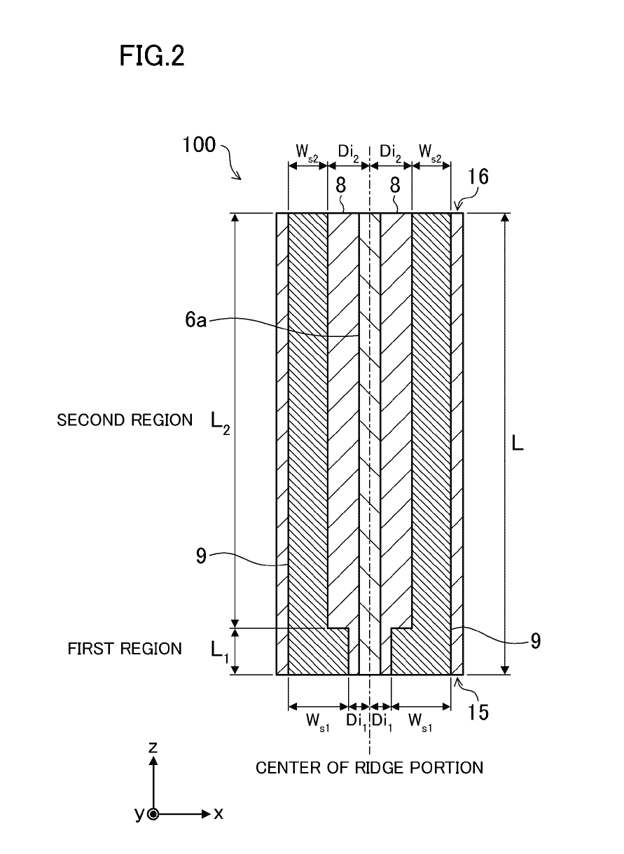

FIG. 2 illustrates a cross-sectional structure of the nitride semiconductor laser diode 100 shown in FIG. 1 taken along the line II-II, and illustrates a planar shape of the light-absorbing layer 9 in the cavity length direction (the emitting direction of laser light).

The nitride semiconductor laser diode 100 shown in FIG. 2 has a cavity length L of 800 μm.

The light-absorbing layer 9 includes a first region provided at the side of a front facet 15 which is an emitting facet of laser light, and a second region formed continuously from the first region to a rear facet 16 which is opposite to the front facet 15. In the first region, the distance from the center of the ridge portion 6a to the side surface of the light-absorbing layer 9 at the side of the ridge portion 6a is set to Di1. In the second region, the distance from the center of the ridge portion 6a to the side surface of the light-absorbing layer 9 at the side of the ridge portion 6a is set to Di2. The distance Di1 is smaller than the distance Di2. As an example, the distance Di1 is set to 1.5 μm, and the distance Di2 is set to 3.0 μm. The length L1 of the first region in the light-absorbing layer 9 in the cavity length direction (the emitting direction of laser light) is set to 40 μm, and the width WS1 is set to 4.5 μm. On the other hand, the length L2 of the second region in the light-absorbing layer 9 in the cavity length direction (the emitting direction of laser light) is set to 760 μm, and the width WS2 is set to 3.0 μm.

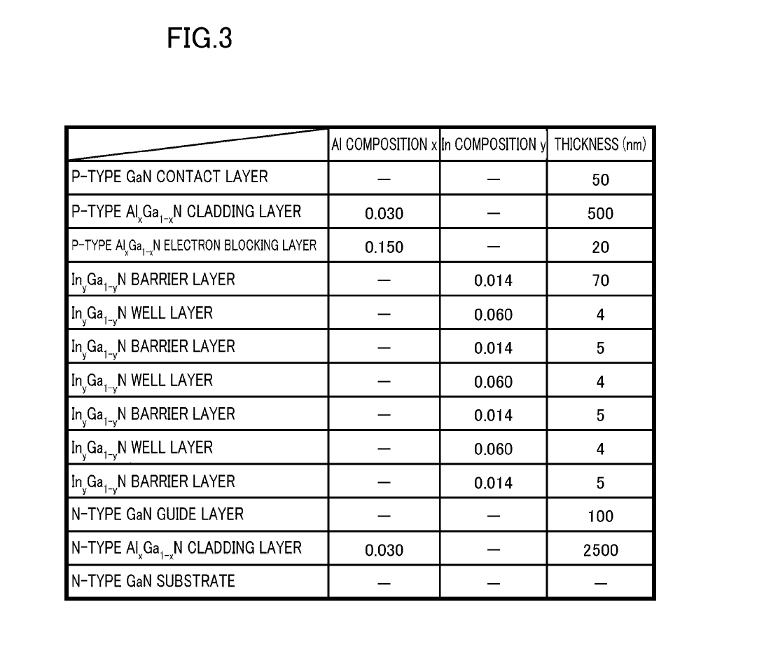

FIG. 3 illustrates examples of the Al composition, the In composition, and the thickness of each if the nitride semiconductor layers of the nitride semiconductor laser diode 100 according to the first example embodiment. The Al composition, the In composition, and the thickness in the nitride semiconductor laser diode 100 shown in FIG. 3 are set so that the kink level is 350 mW or more.

Next, operation of the nitride semiconductor laser diode 100 achieving high-output characteristics and a wide angle of horizontal FFP in the first example embodiment will be described below.

When the output of the semiconductor laser diode 100 is tried to be increased, higher-order transverse mode light is generated in the output light, and then, the horizontal FFP of the output light tends to be narrow. Therefore, in order to raise the kink level of the semiconductor laser diode 100 to obtain satisfactory high-output characteristics, the generation of the higher-order transverse mode light need to be reduced by reducing the difference ΔN in the effective refractive index between the ridge portion 6a and the flat portions 6b in the p-type cladding layer 6 to reduce optical confinement capabilities in the horizontal direction. The kink level of 350 mW or more needs to be realized also in the cross-sectional structure of the nitride semiconductor laser diode 100 in this embodiment. Thus, not only the set values shown in FIG. 3, the thickness (film thickness) d of the flat portions 6b of the p-type cladding layer 6 is set so that the ridge width W satisfies the kink level of 350 mW or more. Furthermore, the light-absorbing layer 9 has the advantage of absorbing leakage light leaking outside from the ridge portion 6a to reduce ripples occurring in the FFP.

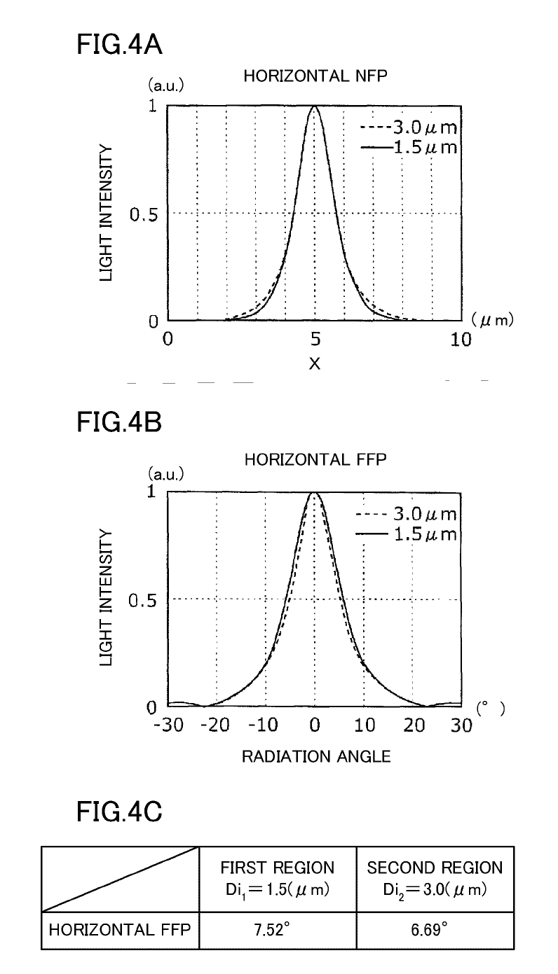

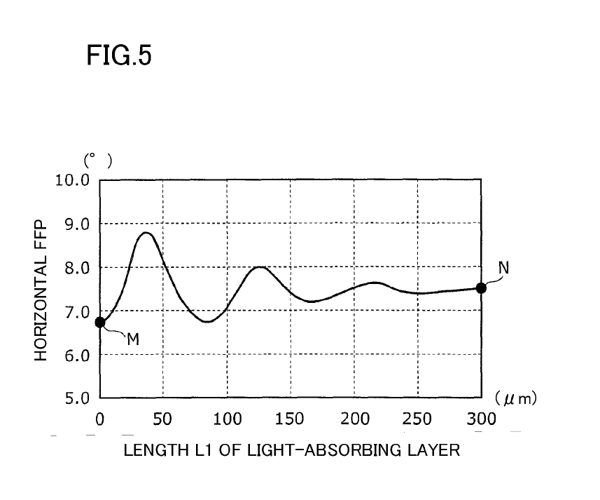

FIGS. 4A-4C illustrate calculation results of the near field pattern in the horizontal direction (horizontal NFP) and far field pattern in the horizontal direction (horizontal FFP) in the nitride semiconductor laser diode 100 shown in FIGS. 1-3, in which the light-absorbing layer includes a first region and a second region. FIG. 4A illustrates the calculation result of the horizontal NFP. FIG. 4B illustrates the calculation result of the horizontal FFP. FIG. 4C illustrates calculated values of the horizontal FFP where laser light has a relative intensity ratio of 0.5 in the first and second regions. Note that, in FIGS. 4A and 4B, the horizontal NFP and the horizontal FFP in the first region are indicated by solid lines, and the horizontal NFP and the horizontal FFP in the second region are indicated by dashed lines. The horizontal NFP is represented by a beam radius (μm) and the horizontal FFP is represented by a radiation angle (“deg” or “°”).

As shown in FIG. 4C, as a result of the calculation, the horizontal FFP in the first region is 7.52°, and the horizontal FFP in the second region is 6.69°. As such, the first region, which has the distance Di1 from the center of the ridge portion to the light-absorbing layer 9 smaller than the distance Di2 in the second region from the center of the ridge portion to the light-absorbing layer 9, has a wider horizontal FFP. This is because, the first region, which has a smaller distance from the center of the ridge portion to the light-absorbing layer 9 than the second region, easily absorbs the foot of fundamental transverse mode light leaking outside the ridge portion 6a by the light-absorbing layer 9, e.g., as shown in FIG. 4A, laser light with a beam radius ranging from 4 μm to 6 μm. That is, laser light with a beam radius out of the predetermined range is absorbed by the light-absorbing layer 9. As a result, as shown in FIG. 4A, the horizontal NFP of the first region is narrower than the horizontal NFP of the second region, and as shown in FIG. 4B, the horizontal FFP which is Fourier transform of the horizontal NFP is wider. As such, in the cross-sectional structure of the nitride semiconductor laser diode 100, the distance D1 in the first region in the light-absorbing layer 9 from the center of the ridge portion to the side surface at the side of the ridge portion 6a is set smaller than the distance D2 in the second region in the light-absorbing layer 9 from the center of the ridge portion to the side surface at the side of the ridge portion 6a, thereby increasing absorption at the foot of the horizontal NFP to increase the angle of the horizontal FFP. This stabilizes the far field pattern (FFP) characteristics.

FIG. 5 illustrates the calculation result of the horizontal FFP in the nitride semiconductor laser diode 100 having the structure shown in FIGS. 1 and 2, where the length L1 in the first region in the light-absorbing layer 9 is changed from L1=0 to L1=300. Point M in FIG. 5 shows the calculation result of the horizontal FFP where L1=0, i.e., there is no first region, and the second region is located in the region from the front facet 15 to the rear facet 16. Furthermore, point N shows the calculation result of the horizontal FFP where L1=300, i.e., the first region is the region being 300 μm from the front facet 15. It can be seen from FIG. 5 that the horizontal FFP fluctuates with a change in the length L1 of the first region in the light-absorbing layer 9, and converges to 7.52°, which is the horizontal FFP in a stationary state of the first region shown in FIG. 5 while fluctuating, when the length L1 is about 250 μm.

When the length L1 of the first region in the light-absorbing layer 9 is 100 μm or less, the horizontal FFP fluctuates at an angle wider than 7.52° which is the convergence point of the horizontal FFP in the first region. The calculation result shows that the maximum value of the horizontal FFP is 8.77° where the length L1 is 40 μm. This it the phenomenon caused by a mode mismatch between the shapes of the fundamental transverse mode light in the first region (hereinafter referred to as “first fundamental transverse mode light”) and fundamental transverse mode light in the second region (hereinafter referred to as “second fundamental transverse mode light”).

When the second fundamental transverse mode light in the second region propagating from the direction of the rear facet 16 propagates to the boundary with the first region, the mode mismatch with the first fundamental transverse mode light in the first region causes interference at the boundary between the first region and the second region. Then, the second fundamental transverse mode light passes through the first region while oscillating so that the mode of the light converges to the first fundamental transverse mode light, and reaches the front facet 15. Thus, in the region near the boundary between the first region and the second region, the mode mismatch between the first fundamental transverse mode light and the second fundamental transverse mode light is large, the fundamental mode light propagates while rapidly oscillating. At this time, a component of the mode of the fundamental transverse mode light is radiated outside the ridge portion 6a as radiation mode light in the process in which the fundamental transverse mode light is converted from the second fundamental transverse mode light to the first fundamental transverse mode light. The most part of the component is absorbed by the light-absorbing layer 9.

As such, the difference ΔN in the effective refractive index of the cross-sectional structure of the second region is reduced to obtain satisfactory high-output characteristics, and the length L1 of the first region in the light-absorbing layer 9 is controlled, thereby actively using the interference of the fundamental transverse mode light with the second region. This makes the value of the horizontal FFP in the first region larger than the value of the horizontal FFP in the second region to increase the angle.

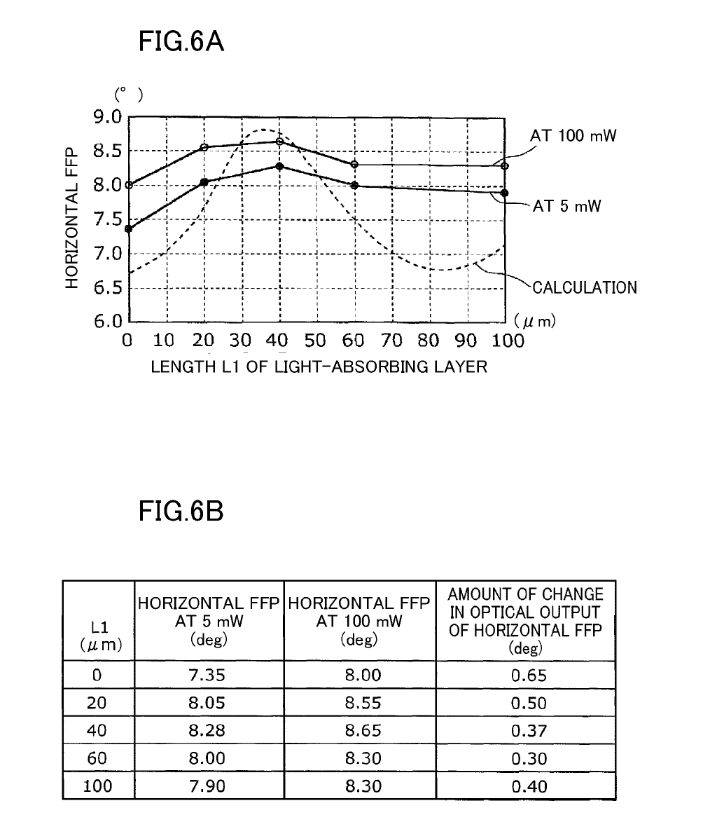

FIGS. 6A and 6B illustrate measured values and calculated values of the horizontal FFPs, where laser light has low-output power (5 mW) and high-output power (100 mW) in samples of the nitride semiconductor laser diode 100 with the lengths L1 of the first region in the light-absorbing layer 9 at the levels of 0 μm, 20 μm, 40 μm, 60 μm, and 100 μm. Note that, twenty samples of the nitride semiconductor laser diode 100 are used for analyzing the horizontal FFPs at each level, the measured values of the horizontal FFPs in FIGS. 6A and 6B are plotted mean values.

In FIG. 6A, where the length L1 is 40 μm, the horizontal FFP is at the highest angle of 8.28° in the low-output operation of 5 mW. That result shows that the angle of the horizontal FFP can be increased by 0.93° from 7.35° of the horizontal FFP in the operation of 5 mW, where the length L1 is 0 μm (in the structure in which a wide first region is not provided in the light-absorbing layer 9). As such, it can be seen that the tendency of the change in the horizontal FFPs according to the lengths L1 of the first region in the light-absorbing layer 9 in the samples of the nitride semiconductor laser diode 100 coincides with the calculated values.

Furthermore, FIGS. 6A and FIG. 6B show the relationship between the length L1 of the first region in the light-absorbing layer 9 in each of the samples of the nitride semiconductor laser diode 100, and the difference between the optical outputs of the horizontal FFPs in the operation of 5 mW and 100 mW. It can be seen that, with an increase in the length L1, the amount of change in the optical output of the horizontal FFP decreases. While the amount of change in the optical output of the horizontal FFP is 0.65° where the length L1 is 0 μm, the amount of change in the optical output of the horizontal FFP decreases by half to 0.30° where the length L1 is 60 μm. The amount of change in the optical output of the horizontal FFP occurs, since the foot of the first fundamental transverse mode light in the first region shown in FIG. 4A is absorbed by the light-absorbing layer 9 even in low-output operation to narrow the horizontal NFP so that the horizontal NFP is less affected by an increase in the difference ΔN in the effective refractive index in high-output operation. Thus, the nitride semiconductor laser diode 100 according to the first example embodiment can reduce the amount of change in the optical output of the horizontal FFP by using the first region in the light-absorbing layer 9 which has a small distance from the ridge portion 6a.

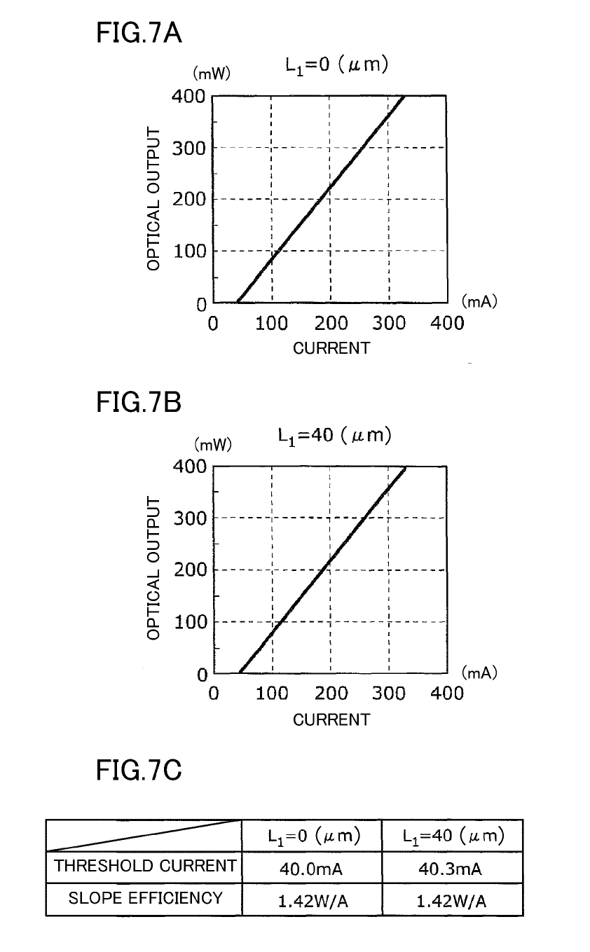

FIGS. 7A-7C illustrate optical output-current characteristics (hereinafter referred to as “L-I characteristics”) of representative ones of the nitride semiconductor laser diodes 100 with the lengths L1 of 0 μm and 40 μm, which are analyzed in FIGS. 6A and 6B. As shown in FIG. 7A, the nitride semiconductor laser diode 100 with the length L1 of 0 μm has an optical output of about 350 mW where a current is 300 mA. As shown in FIG. 7B, the nitride semiconductor laser diode 100 with the length L1 of 40 μm also has an optical output of about 350 mW where a current is 300 mA. That is, in the both cases where the length L1 is 0 μm and 40 μm, the kink level is 350 mW or more. It can be seen that the L-I characteristics where the length L1 of the first region in the light-absorbing layer 9 is 40 μm are equal to the L-I characteristics of the nitride semiconductor laser diode 100 with the length L1 of 0 μm. Furthermore, as shown in FIG. 7C, it can be seen that the threshold current and the slope efficiency of the nitride semiconductor laser diode 100 with the length L1 of 40 μm are substantially equal to those of the nitride semiconductor laser diode 100 with the length L1 of 0 μm.

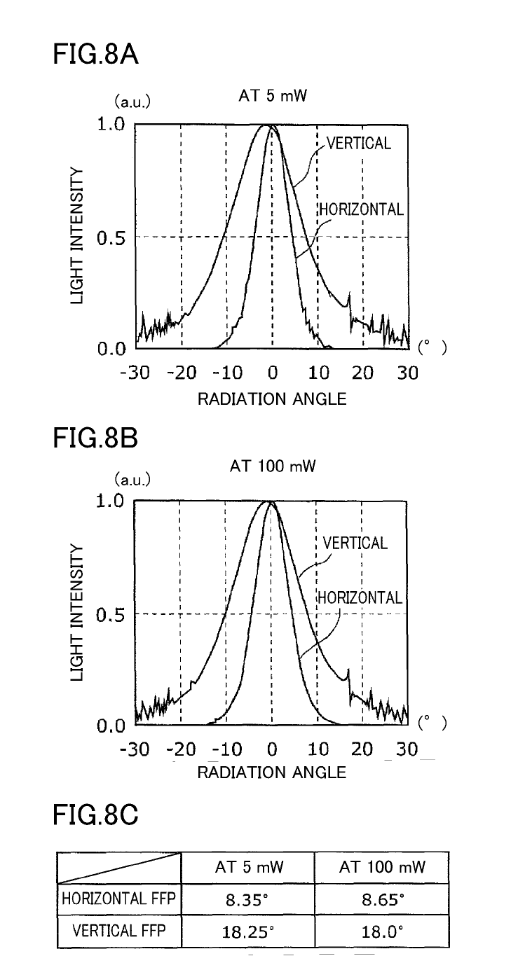

FIGS. 8A-8C illustrate the FFP waveforms of the nitride semiconductor laser diode 100 with the length L1 of the first region in the light-absorbing layer 9 of 40 μm, which is analyzed in FIG. 7B. In FIG. 8A, the FFP is 8.35° in the horizontal direction and 18.25° in the vertical direction where laser light power is 5 mW (in low-output operation), and the FFP is 8.65° in the horizontal direction and 18.0° in the vertical direction where laser light power is 100 mW (in high-output operation). Good FFP waveforms can be obtained without causing any ripple in the region where the relative intensity ratio is 0.5 or more. As such, it can be seen that, even when the distance Di1 between the light-absorbing layer 9 and the center of the ridge portion in the first region is reduced to 1.5 μm in the range of 40 μm from the front facet 15, the angle of the horizontal FFP can be increased without damaging laser characteristics such as the threshold current, slope efficiency, and the kink level.

As such, in the nitride semiconductor laser diode 100 according to the first example embodiment, the distance Di1 from the center of the ridge portion to the side surface of the light-absorbing layer 9 at the side of the ridge portion 6a is as small as Di1=1.5 μm in the first region at the side of the front facet 15. On the other hand, the distance Di2 is as large as Di2=30 μm in the second region at the opposite side to the front facet 15. Furthermore, the length L1 in the first region is set to L1=40 μm, thereby utilizing the interference caused by the mode mismatch of fundamental transverse mode light between the first region and the second region, thereby increasing the angle of the horizontal FFP.

Note that, in the nitride semiconductor laser diode 100 according to the first example embodiment, when the light-absorbing layer 9 is not provided in the second region, the horizontal NFP in the second region without the light-absorbing layer 9 is distorted by the influence of stray light leaking outside the ridge portion 6a. Thus, unless the length L1 in the first region at the front facet 15 is increased compared to the case where the second region has the light-absorbing layer 9, ripples can easily occur in the horizontal FFP. It is not preferable to set the length L1 of the first region in the light-absorbing layer 9 large to reduce the ripples of the horizontal FFP, since, as shown in FIGS. 6A and 6B, the amount of change in the horizontal FFP is reduced and laser characteristics are damaged. For example, the threshold current is increased, and the slope efficiency is reduced due to an increase in absorption of fundamental transverse mode light by the light-absorbing layer 9 in the first region. Thus, in order to minimize damages to the basic characteristics as a laser to increase the angle of the horizontal FFP and to reduce the ripples of the horizontal FFP, the length L1 of the first region in the light-absorbing layer 9 need to be as short as possible. Therefore, the light-absorbing layer 9 needs to be introduced to the second region to remove distortion of the horizontal NFP of the second region.

In the first example embodiment, the Al composition, the In composition, and the thickness of each of the nitride semiconductor layers are set as shown in FIG. 3. Clearly, such values may be changed when the maximum optical output and the value of the FFP in the nitride semiconductor laser diode 100 are changed.

While the thickness d of the flat portions 6b of the p-type cladding layer 6 is set to 50 nm, the thickness d of the flat portion 6b may be changed when the value of the FFP is changed. In this case, in order to set the horizontal FFP within a range from 6° to 10°, which is optimum as a light source for Blu-ray Discs, the thickness d of the flat portion 6b of the p-type cladding layer 6 needs to be set within a range from 10 nm to 70 nm.

The ridge width W preferably ranges from 1.1 μm to 1.7 μm. This is because, where the ridge width W is less than 1.1 μm, the series resistance increases in the nitride semiconductor laser diode 100 to raise the operating voltage. Where the ridge width W is more than 1.7 μm, the guided mode condition in the nitride semiconductor laser diode 100 does not satisfy the single mode condition, thereby lowering the kink level due to the generation of the higher-order transverse mode light.

The distance Di1 between the light-absorbing layer 9 at the side of the front facet 15 and the center of the ridge portion in the first region needs to range from 1 μm to 2.0 μm. When the distance Di1 is less than 1 μm, the fundamental transverse mode light in the nitride semiconductor laser diode 100 is absorbed by the light-absorbing layer 9 to increase the threshold current, reduce the slope efficiency, and generate heat with the light-absorbing layer 9 serving as a thermal absorbing body. This damages the long-term reliability of the semiconductor laser diode 100. When the distance Di1 is more than 2.0 μm, the mode mismatch of the fundamental transverse mode light at the boundary between the first region and the second region decreases to reduce the amount of change in the horizontal FFP.

The length L1 of the first region is set within a range from 10 μm to 100 μm. This is because the amount of the increase in the horizontal FFP is small where the length L1 is less than 10 μm. Where the length L1 is more than 100 μm, the amount of change in the horizontal FFP decreases and the absorption of the fundamental transverse mode light increases to damage laser characteristics, e.g., an increase in the threshold current and a decrease in the slope efficiency.

The distance Di2 between the light-absorbing layer 9 and the center of the ridge portion in the second region needs to be 2.5 μm or more. When the distance Di2 is less than 2.5 μm, the absorption of the fundamental transverse mode light increases as in the distance Di1 of the first region to damage the basic characteristics of the laser, e.g., an increase in the threshold current and a decrease in the slope efficiency.

The width WS1 of the first region in the light-absorbing layer 9 is set within a range from 4 μm to 25 μm. When the width WS1 is less than 4 μm, the absorption of light leaking outside the ridge portion 6a becomes weak, thereby causing ripples to distort the FFP waveform. When the width WS1 is more than 2.5 μm and the light-absorbing layer 9 is made of α-Si and the like, the adhesiveness between the light-absorbing layer 9 and the insulating film 8 is reduced to deteriorate processability of the nitride semiconductor laser diode, thereby reducing the yield of the assembly process.

The thickness of the first region in the light-absorbing layer 9 is set within a range from 20 nm to 140 nm. When the thickness of the light-absorbing layer 9 made of α-Si and the like is less than 20 nm, the absorption of the foot of the fundamental transverse mode light becomes weak to reduce the mode mismatch of the fundamental transverse mode light at the boundary between the first region and the second region. As a result, the amount of the increase in the horizontal FFP becomes small. When the thickness of the light-absorbing layer 9 is more than 140 nm, the light-absorbing layer 9 may be easily destroyed so that the insulating film 8 may be removed at the boundary between the insulating film 8 and the light-absorbing layer 9 to cause damages such as current leakage and deterioration of the processability.

As described above, in the nitride semiconductor laser diode 100 according to the first example embodiment, the distance Di1 between the light-absorbing layer 9 at the side of the front facet 15 and the center of the ridge portion in the first region is smaller than the distance Di2 between the light-absorbing layer 9 at the opposite side to the front facet 15 and the center of the ridge portion in the second region. Thus, the light-absorbing layer 9 absorbs the foot of the fundamental transverse mode light leaking outside the ridge portion 6a of the p-type cladding layer 6, i.e., a part of laser light having a beam radius larger than a predetermined size. As a result, even in laser light has high-output power, the angle of the horizontal FFP of the nitride semiconductor laser diode 100 can be increased without increasing the difference ΔN in the effective refractive index. Therefore, the nitride semiconductor laser diode 100 preferable as a light source for Blu-ray Discs can be realized.

### First Variation of First Example Embodiment

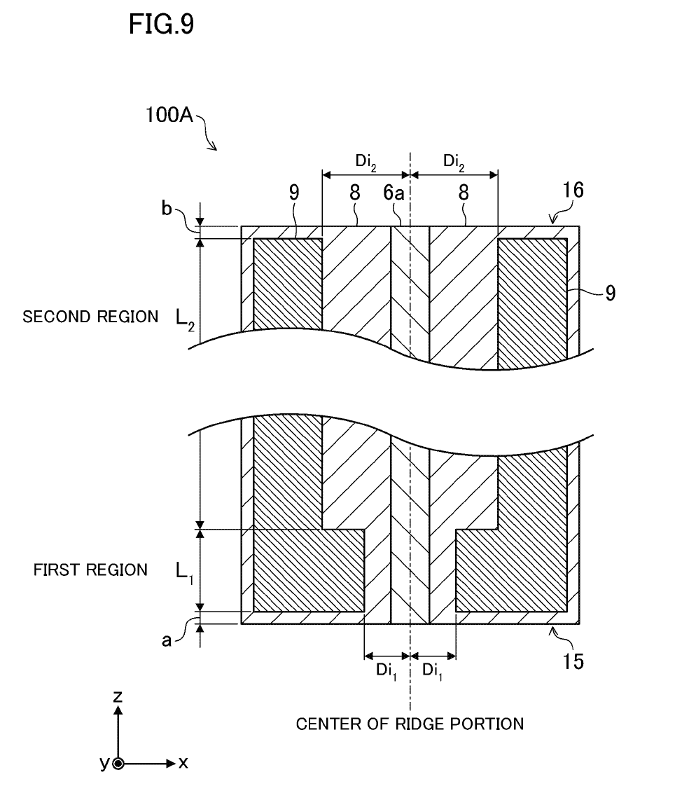

A first variation of the first example embodiment will be described hereinafter with reference to FIG. 9.

As shown in FIG. 9, in the nitride semiconductor laser diode 100A according to the first variation, the light-absorbing layer 9 is spaced apart from the front facet 15 with a predetermined first space a, and similarly, from the rear facet 16 with a predetermined second space b.

When each of the first space a from the front facet 15 and the second space b from the rear facet 16 ranges from 0 μm to 10 μm, the amount of change in the horizontal FFP and the amount of change in the optical output in the first region lead to similar results to those in the nitride semiconductor laser diode 100 according to the first embodiment shown in FIGS. 1 and 2.

Note that, when each of the first space a and the second space b is more than 10 μm, laser light propagates to the front facet 15 with the horizontal NFP expanding in the region without the light-absorbing layer 9 to reduce the amount of change in the horizontal FFP.

### Second Variation of First Example Embodiment

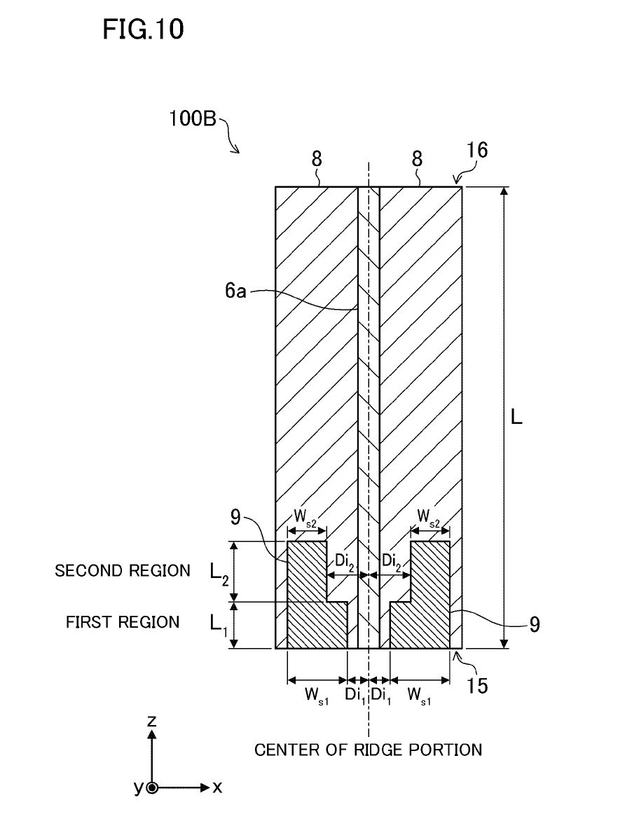

A second variation of the first example embodiment will be described hereinafter with reference to FIG. 10.

As shown in FIG. 10, in a nitride semiconductor laser diode 100B according to the second variation, the minimum value of the length of the second region, which is continuous with the first region in the light-absorbing layer 9, is defined. Specifically, the length L2 of the second region in the light-absorbing layer 9 needs to be at least 30 μm. This is because, as described above, the second region in the light-absorbing layer 9 is provided to reduce distortion of the waveform of the horizontal NFP due to stray light, and the length L2 needs to be sufficiently large to absorb the stray light in the second region.

For example, as shown in FIG. 10, even if the light-absorbing layer 9 is formed so that the length L1 of the first region in the light-absorbing layer 9 is 40 μm, and the length L2 of the second region in the light-absorbing layer 9 is 60 μm, the mode mismatch of the fundamental transverse mode light occurs at the boundary between the first region and the second region. As a result, the same results as in the nitride semiconductor laser diode 100 according to the first example embodiment shown in FIGS. 1 and 2 are obtained with respect to the amount of change in the horizontal FFP, the waveform of the horizontal FFP and the amount of change in the optical output in the first region.

### Third Variation of First Example Embodiment

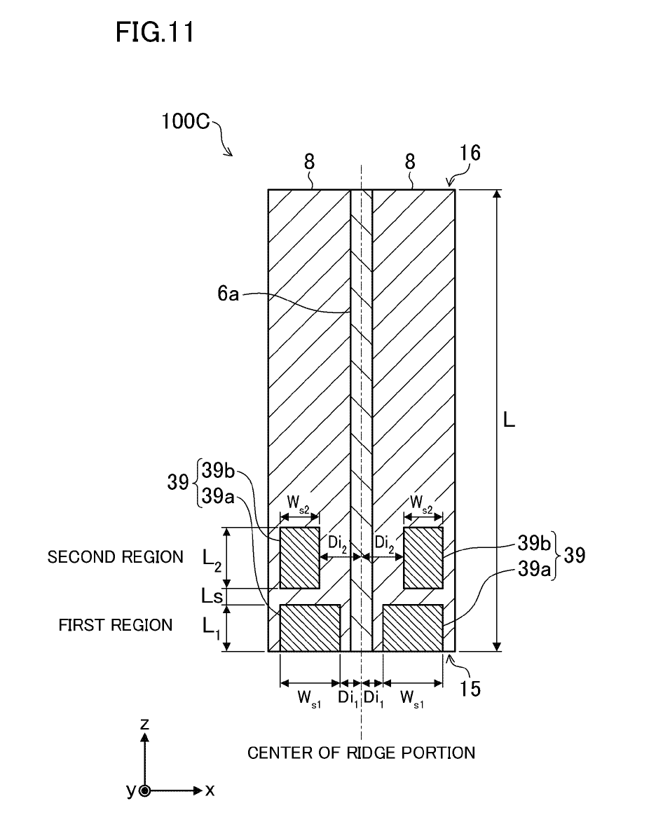

A third variation of the first example embodiment will be described hereinafter with reference to FIG. 11.

As shown in FIG. 11, in a nitride semiconductor laser diode 100C according to the third variation, a light-absorbing layer 39 includes a first light-absorbing layer 39a, and a second light-absorbing layer 39b. The first light-absorbing layer 39a formed in the first region is spaced apart from the second light-absorbing layer 39b formed in the second region with a space Ls interposed therebetween.

The space Ls between the first region and the second region is preferably 10 μm or less. This is because, little distortion occurs in the waveform of the horizontal NFP when the space Ls is 10 μm or less. This reduces effects on the distortion of the waveform of the horizontal FFP at the front facet 15 which is an emitting facet of laser light.

Furthermore, when the space Ls is 10 μm or less, the spread of the horizontal NFP in the second region is small. Even when the space Ls of 10 μm or less is provided, the same results as in the nitride semiconductor laser diode 100 according to the first example embodiment shown in FIGS. 1 and 2 are obtained with respect to the amount of change in the horizontal FFP, the waveform of the horizontal FFP and the amount of change in the optical output in the first region caused by the mode mismatch of the fundamental transverse mode light.

If the space Ls between the first region and the second region is more than 10 μm, distortion occurs in the waveform of the horizontal NFP due to the space Ls more than 10 μm to increase the distortion in the waveform of the horizontal FFP at the front facet 15. Thus, the space Ls more than 10 μm is not preferable.

### Second Example Embodiment

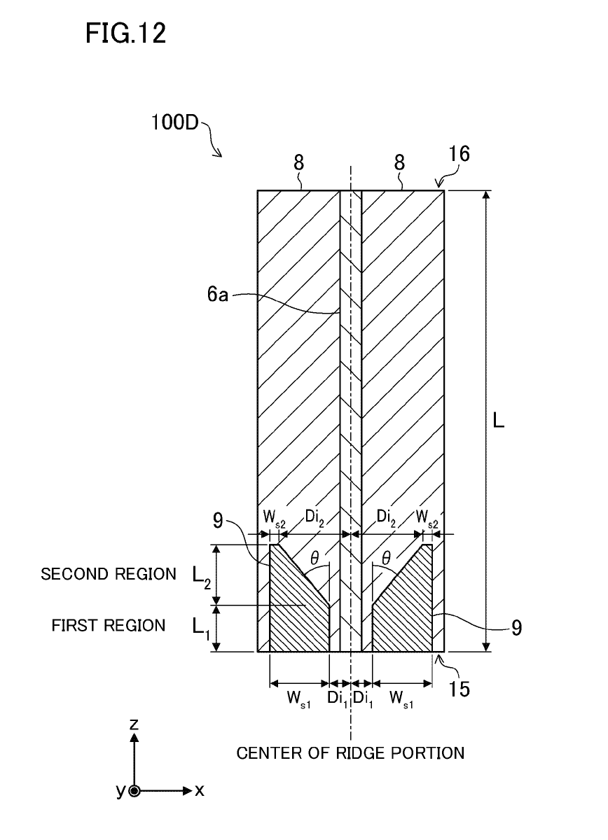

A nitride semiconductor laser diode according to a second example embodiment will be described hereinafter with reference to FIGS. 12-14. The same reference numerals as those shown in FIG. 2 are used to represent equivalent elements, and the explanation thereof will be omitted.

As shown in FIG. 12, a nitride semiconductor laser diode 100D according to the second example embodiment has a planer shape, in which the light-absorbing layer 9 continuously changes from the first region to the second region.

Specifically, the light-absorbing layer 9 is formed so that the distance Di from the center of the ridge portion 6a in the cladding layer 6 to the side surface of the light-absorbing layer 9 at the side of the ridge portion 6a continuously changes in the second region from the distance Di1 to the distance Di2 in the direction from the front facet 15 to the rear facet 16.

The distance Di1 is smaller than the distance Di2 as in the first example embodiment except for the boundary of the first region and the second region. As an example, the distance Di1 is set to 1.5 μm, and the distance Di2 is set to 6.0 μm. The length L1 of the first region in the light-absorbing layer 9 in the cavity length direction is set to 40 μm, the width WS1 is set to 7.5 μm. On the other hand, the length L2 of the second region in the light-absorbing layer 9 in the cavity length direction is set to 60 μm, and the minimum width WS2 is set to 3.0 μm.

When the distance Di1, the distance Di2, and the length L2 are at the value as above, the angle θ between the side surface of the ridge portion 6a and the oblique line of the second region in the light-absorbing layer 9 (hereinafter simply referred to as the “angle θ”) is 4.29°.

The nitride semiconductor laser diode 100D according to the second example embodiment utilizes, similar to the nitride semiconductor laser diode 100 according to the first example embodiment, the interference of the fundamental transverse mode light between the first region and the second region. This makes the value of the horizontal FFP in the first region larger than the value of the horizontal FFP in the second region to increase the angle.

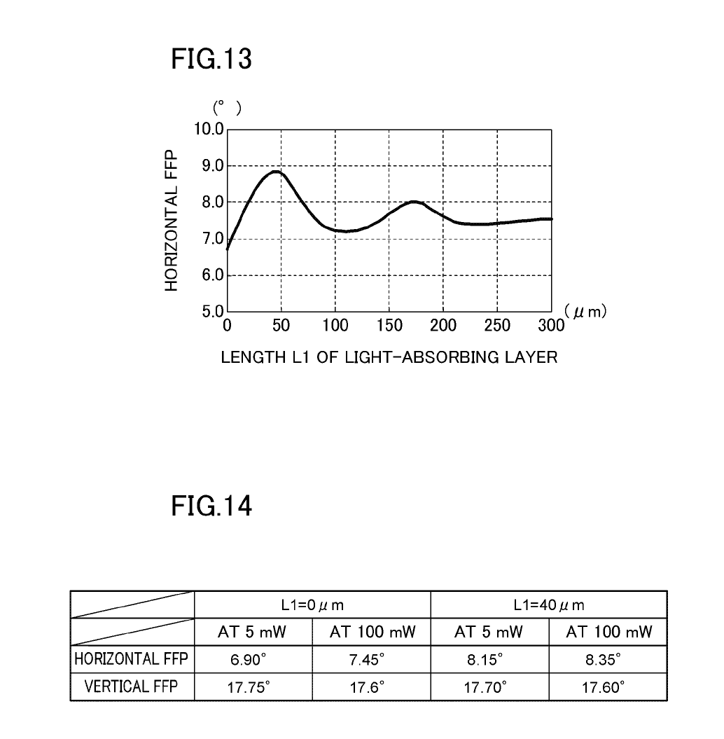

FIG. 13 illustrates the calculation result of the horizontal FFP where the length L1 of the first region in the light-absorbing layer 9 is changed from 0 μm to 300 μm in the nitride semiconductor laser diode 100D of the second example embodiment.

As shown in FIG. 13, similar to the first example embodiment, the horizontal FFP fluctuates in accordance with the length L1 of the first region in the light-absorbing layer 9. This is because, similar to the first example embodiment, when the second fundamental transverse mode light in the second region propagating from the rear facet propagates to the boundary with the first region, the mode mismatch with the first fundamental transverse mode light in the first region causes interference at the boundary between the first region and the second region.

The calculation result shows that the maximum value of the horizontal FFP is 8.80° where the length L1 is 40 μm, which is larger than that in the first example embodiment by 0.03°. This is because, the Di from the center of the ridge portion to the light-absorbing layer 9 continuously changes from Di2 to Di1 in the direction from the rear facet 16 to the front facet 15, and thus, the second fundamental transverse mode light propagates through the second region in the direction from the rear facet 16 to front facet 15 while converting the mode to reach the boundary between the first region and the second region. Therefore, the second fundamental transverse mode light at the boundary between the first region and the second region in a different state of interference due to the mode mismatch with the first region from the second fundamental transverse mode light in the first example embodiment.

FIG. 14 illustrates the measurement result of the horizontal FFP and the vertical FFP in samples of the nitride semiconductor laser diode 100D according to the second example embodiment, where the lengths L1 of the first region in the light-absorbing layer 9 is 0 μm and 40 μm and where laser light has power of 5 mW and 100 mW.

Forty samples are used for the analysis, the values of the horizontal FFP and the vertical FFP shown FIG. 14 are the mean values. As can be seen from FIG. 14, the horizontal FFP in the operation of 5 mW is 6.90° where the length L1 of the first region is 0 μm. On the other hand, the horizontal FFP in the operation of 5 mW is 8.15° where the length L1 of the first region is 40 μm. That is, the angle of the horizontal FFP can be increased only by 1.25°. Similarly, in the operation of 100 mW, where the length L1 of the first region is 40 μm, the angle of the horizontal FFP can be increased only by 0.9° compared to the case where the length L1 of the first region is 0 μm. On the other hand, the vertical FFP in the operation of 5 mW is 17.75° where the length L1 of the first region is 0 μm, and similarly, the vertical FFP is 17.70° where the length L1 of the first region is 40 μm. The results are substantially the same.

As described above, in the nitride semiconductor laser diode 100D according to the second example embodiment, the first region in the light-absorbing layer 9 provided at the side of the front facet 15 is spaced apart from the center of the ridge portion with a distance Di1. The second region in the light-absorbing layer 9 provided at the opposite side to the front facet 15 is formed to continuously expand the distance Di1 between the center of the ridge portion and the second region to the distance Di2. This provides the advantage of increasing the angle of the horizontal FFP similarly to the first example embodiment.

Note that the distance Di1, the distance Di2, and the length L2 in the second region are preferably set within ranges similar to those in the first example embodiment so that the angle θ is 1.4° or more. If the angle θ is less than 1.4°, the mode of the fundamental transverse mode light in the second region is slowly converted to reduce the mode mismatch between the second fundamental transverse mode light and the first fundamental transverse mode light at the boundary between the first region and the second region. As a result, oscillation of the fundamental transverse mode light is reduced also in the first region to mitigate an increase in the size of the horizontal FFP.

When the angle θ is set to 1.4° or more, desired advantages can be obtained for the reasons similar to those in the first example embodiment; when the length, width, thickness of the light-absorbing layer 9, the sizes of the ridge portion 6a such as the ridge width W, and the thicknesses and the compositions of the nitride semiconductor layers forming the nitride semiconductor laser diode 100D are in ranges similar to those in the first example embodiment.

Similar to the first variation of the first example embodiment shown in FIG. 9, the first region may be spaced apart from the front facet 15 with a first predetermined space a, and from the rear facet 16 with a second predetermined space b (not shown). Similar to the first variation, when each of the first space a from the front facet 15 and the second space b from the rear facet 16 ranges from 0 μm to 10 μm, similar advantages to the nitride semiconductor laser diode 100D according to the second example embodiment shown in FIG. 12 can be obtained with respect to the amount of change in the horizontal FFP and the amount of change in the optical output in the first region.

Furthermore, similar to the third variation of the first example embodiment shown in FIG. 11, the first region and the second region in the light-absorbing layer may be arranged with a space Ls interposed therebetween (not shown). In this case, the space Ls is preferably 10 μm or less for similar reasons to the third variation. When the space Ls is 10 μm or less, the advantage of increasing the angle of the horizontal FFP can be obtained for similar reasons to the third variation.

### Third Example Embodiment

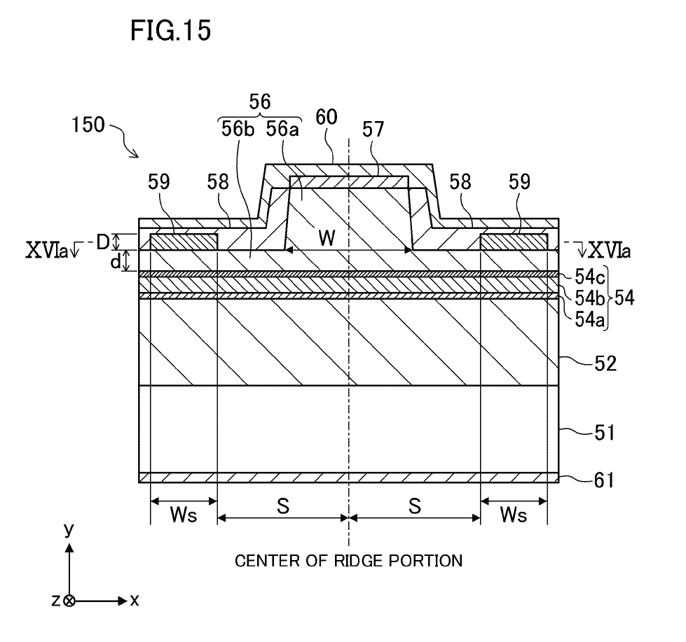

A nitride semiconductor laser diode according to a third example embodiment will be described hereinafter with reference to FIGS. 15-22.

The nitride semiconductor laser diode according to the third example embodiment has a cavity structure extending in the emitting direction of laser light, and outputs laser light with the oscillation wavelength of 405 nm using laser oscillation.

For example, the nitride semiconductor laser diode according to the third example embodiment includes an n-type cladding layer formed on a substrate made of n-type gallium nitride (GaN); an active layer formed on the n-type cladding layer and having a quantum well structure; an optical guide layer formed under the active layer, and guiding laser light generated in the active layer; an overflow barrier layer formed on the active layer, and blocking overflow of carriers injected into the active layer; a p-type cladding layer formed on the overflow barrier layer, and having a raised ridge portion extending in a longitudinal direction of the cavity (the emitting direction of laser light) and flat portions provided on both sides of the ridge portion; a light-absorbing layer formed on each of the flat portions on the both sides of the ridge portion to be spaced apart from the ridge portion, and having an optical absorption coefficient larger than the p-type cladding layer with respect to an oscillation wavelength; and an insulating film formed on the p-type cladding layer and the light-absorbing layer.

The light-absorbing layer includes a first region; in which S1 is the distance from the center of the ridge portion, which is parallel to the emitting direction of laser light and is a line-symmetric axis of the ridge portion, to the side surface of the light-absorbing layer at the side of the ridge portion. The light-absorbing layer has a thickness D1 in the first region. The light-absorbing layer also includes a second region which is connected to the first region. In the second region, S2 is the distance from the center of the ridge portion to the side surface of the light-absorbing layer at the side of the ridge portion. The light-absorbing layer has a thickness D2 in the second region. The relationship between the distance S1 in the first region and the distance S2 in the second region, and between the thickness d1 in the first region and the thickness d2 in the second region are represented by S1≦S2 and d1>d2. This configuration realizes a nitride semiconductor laser diode which can increase the angle of the horizontal FFP of laser light with an increase in the output of laser light.

An example nitride semiconductor laser diode 150 according to the third example embodiment will be described below with reference to FIG. 15.

As shown in FIG. 15, the nitride semiconductor laser diode 150 according to the third example embodiment includes an n-type cladding layer 52 made of n-type AlₓGa₁₋ₓN, an active layer 54, a p-type cladding layer 56 made of p-type AlₓGa₁₋ₓN, and a p-type contact layer 57 made of p-type GaN; which are sequentially formed on an n-type substrate 51 made of n-type GaN by epitaxial growth; where x represents the aluminum (Al) composition, and y represents the indium (In) composition.

The p-type cladding layer 56 includes a ridge portion 56a in a raised cross-sectional shape, which extends in the emitting direction of laser light and including a cavity, and flat portion 56b which are continuously formed to both sides of the ridge portion 56a. A light-absorbing layer 59, which absorbs laser light with an oscillation wavelength band, is formed on each of the flat portions 56b in the p-type cladding layer 56 at a location spaced apart from each o the side surfaces of the ridge portion 56a. Also, an insulating film 58, which covers the light-absorbing layer 59 and is made of a dielectric material having the functions of current and optical confinement, is formed on the both side surfaces of the ridge portion 56a and on the both flat portions 56b in the p-type cladding layer 56.

In FIG. 15, S denotes the distance from the center of the ridge portion to the side surface of the light-absorbing layer 59 at the side of the ridge portion 56a. Reference character d denotes the thickness of the flat portions 56b in the p-type cladding layer 56, and D and Ws denote the thickness and the width of the light-absorbing layer 59.

The p-type contact layer 57 is formed on the top surface of the ridge portion 56a of the p-type cladding layer 56, i.e., in an exposed portion from the insulating film 58. A p-side electrode 60, which is in ohmic contact with the p-type contact layer 57, is formed on the insulating film 58 and the p-type contact layer 57. On the other hand, an n-side electrode 61, which is in ohmic contact with the n-type substrate 51, is formed on the surface (back surface) of the n-type substrate 51 opposite to the n-type cladding layer 52.

The active layer 54 includes an n-type guide layer 54a made of n-type AlₓGa₁₋ₓN, an active layer 54b made of In_{y}Ga_{1-y}N and having a quantum well structure including a well layer and barrier layers, a p-type electron blocking layer 54c made of p-type AlₓGa₁₋ₓN and blocking overflow of electrons (carriers) from the active layer 54b.

The outline of a manufacturing method of the nitride semiconductor laser diode 150 configured as above will be described below.

First, the layers from the n-type cladding layer 52 to the p-type contact layer 57 are sequentially formed on the n-type substrate 51 by crystal growth using for example, metal organic chemical vapor deposition (MOCVD).

Then, the ridge portion 56a for injecting currents into the active layer 54b and confining light is selectively formed in the p-type cladding layer 56 by lithography and dry etching such as reactive ion etching. At this time, in order to satisfy the oscillation condition of a single transverse mode near the oscillation threshold current value of laser light, dry etching is performed with the ridge portion 56a in the p-type cladding layer 56 having a ridge width W of 1.4 μm, and the flat portions 56b having a thickness d of 50 nm. As shown in FIG. 15, the ridge width W denotes the width of the ridge portion 56a at the boundary between the ridge portion 56a and the flat portions 56b, i.e., the width of the bottom of the ridge portion 56a having a raised cross-sectional shape.

Next, a semiconductor film for forming the light-absorbing layer is deposited over the entire surface of the p-type cladding layer 56 by vacuum vapor deposition etc. After that, the deposited semiconductor film is patterned so that the each of the inner side surfaces is spaced apart from the center of the ridge portion with a distance S on each of the flat portions 56b by lithography and dry etching to form the light-absorbing layer 59 from the semiconductor film. The semiconductor film forming the light-absorbing layer 59 can be made of a semiconductor material such as amorphous silicon (α-Si) or silicon (Si) absorbing light with a wavelength of 405 nm which is the oscillation wavelength of the nitride semiconductor laser diode 150. At this time, the thickness of the light-absorbing layer 59 at the side of the light-emitting facet is formed larger than that in other regions. This increases the angle of the horizontal FFP as described below. Note that, in order to form the light-absorbing layer 59 with various thicknesses depending on portions by selectively reducing the thickness of the region opposite to the light-emitting facet by etching, or by depositing the side of the light-emitting facet and the other regions in two steps.

Then, the insulating film 58, which is made of a dielectric material such as silicon dioxide (SiO₂), silicon nitride (SiN), tantalum oxide (Ta₂O₅) or zirconium dioxide (ZrO₂), is deposited by CVD etc. over the entire surface of the p-type cladding layer 56 including the light-absorbing layer 59. After that, the insulating film 58 in an upper portion of the ridge portion 56a of the p-type cladding layer 56 is selectively removed by lithography and dry etching to expose the top surface of the ridge portion 56a.

Next, the p-side electrode 60 made of a metal multilayer film of e.g. titanium (Ti)/platinum (Pt)/gold (Au) is formed on the insulating film 58 and the top surface of the ridge portion 56a exposed from the insulating film 58 by sputtering, vacuum vapor deposition, or the like. The formed p-side electrode 60 comes into ohmic contact with the p-type contact layer 57.

After that, the n-side electrode 61 made of a metal multilayer film of e.g. titanium (Ti)/platinum (Pt)/gold (Au) is formed on the back surface of the n-type substrate 51 by sputtering, vacuum vapor deposition, or the like. The formed n-side electrode 61 comes into ohmic contact with the n-type substrate 51.

Note that in the nitride semiconductor laser diode 150 according to the third example embodiment, the insulating film 58 is made of silicon dioxide, and the light-absorbing layer 59 is made of α-Si.

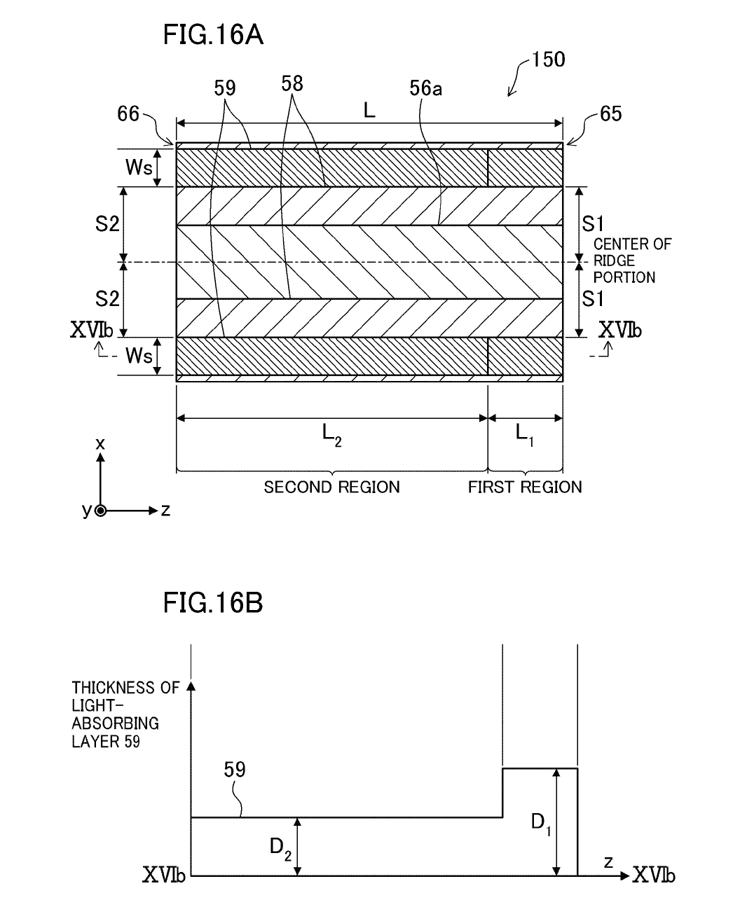

The nitride semiconductor laser diode 150 according to the third example embodiment shown in the cross-sectional view in the direction parallel to the xz plane of FIG. 16A has a cavity length L of 800 μm.

The light-absorbing layer 59 includes a first region provided at the side of a front facet 65 which is an emitting facet of laser light, and a second region formed continuously from the first region to a rear facet 66 which is a reflecting facet.

As shown in FIGS. 16A and 16B, in the first region of the light-absorbing layer 59, the distance from the center of the ridge portion 56a to the side surface of the light-absorbing layer 59 at the side of the ridge portion 56a is set to S1, and the thickness is set to D1. In the second region of the light-absorbing layer 59, D2 is the distance from the center of the ridge portion 56a to the side surface of the light-absorbing layer 59 at the side of the ridge portion 56a is set to S2, and the thickness is set to D2.

The distance S1 is equal to or smaller than the distance S2. The thickness D1 is set larger than the thickness D2. As an example, the distances S1 and S2 are set to 2.5 μm, the thickness D1 is set to 20 nm, and the thickness D2 is set to 2 nm.

The length L1 of the first region of the light-absorbing layer 59 in a longitudinal direction of the cavity (the emitting direction of laser light) is set to 60 μm, and the length L2 of the second region in the longitudinal direction of the cavity is set to 740 μm. The width Ws of the light-absorbing layer 59 is set to 4 μm.

Examples of the Al composition, the In composition, and the thickness of each of the nitride semiconductor layers in the nitride semiconductor laser diode 150 according to the third example embodiment are equal to those in the nitride semiconductor laser diode 100 according to the first example embodiment shown in FIG. 3. The Al composition, the In composition, and the thickness in the nitride semiconductor laser diode 150 shown in FIG. 3 are set so that the kink level is 350 mW or more.

Next, operation of the nitride semiconductor laser diode 150, which achieves stabilization of high-output operation by reducing the thickness of the light-absorbing layer 59, and an increase in the angle of the horizontal FFP by setting the thickness D1 larger than the thickness D2, in the third example embodiment will be described below.

As described above, when the nitride semiconductor laser diode is in a high-output state, a phenomenon called “kinks,” i.e., deterioration of linearity of optical output with respect to injected currents easily occurs. This makes it difficult to obtain stable optical output characteristics. The cause of kinks is an increase in the refractive index of the p-type cladding layer due to the heat of generation at the ridge portion according to an increase in the optical output. This increases the optical confinement capabilities of the ridge portion 56a to easily cause higher-order transverse mode light. The generated higher-order transverse mode light interferes with the fundamental transverse mode light to make laser light unstable, thereby causing the kinks. Therefore, in order to improve the kink level, the higher-order transverse mode light needs to be controlled. Effective methods of controlling the higher-order transverse mode are increasing the thickness d of the flat portions 56b of the p-type cladding layer 56 in the nitride semiconductor laser diode 150 to reduce the difference ΔN in the effective refractive index, thereby reducing the optical confinement capabilities in the horizontal direction to increase the single mode condition; and reducing the influence of the higher-order transverse mode on the fundamental transverse mode.

An improvement in the kink level according to the third example embodiment is achieved by utilizing the latter method of reducing the influence of the higher-order transverse mode on the fundamental transverse mode, and its advantage. The light-absorbing layer 59, which absorbs light with a wavelength of 405 nm which is the oscillation wavelength of the nitride semiconductor laser diode 150, absorbs only the higher-order transverse mode light and attenuates the light. This reduces the interference between the fundamental transverse mode light and the higher-order transverse mode light to improve the kink level.

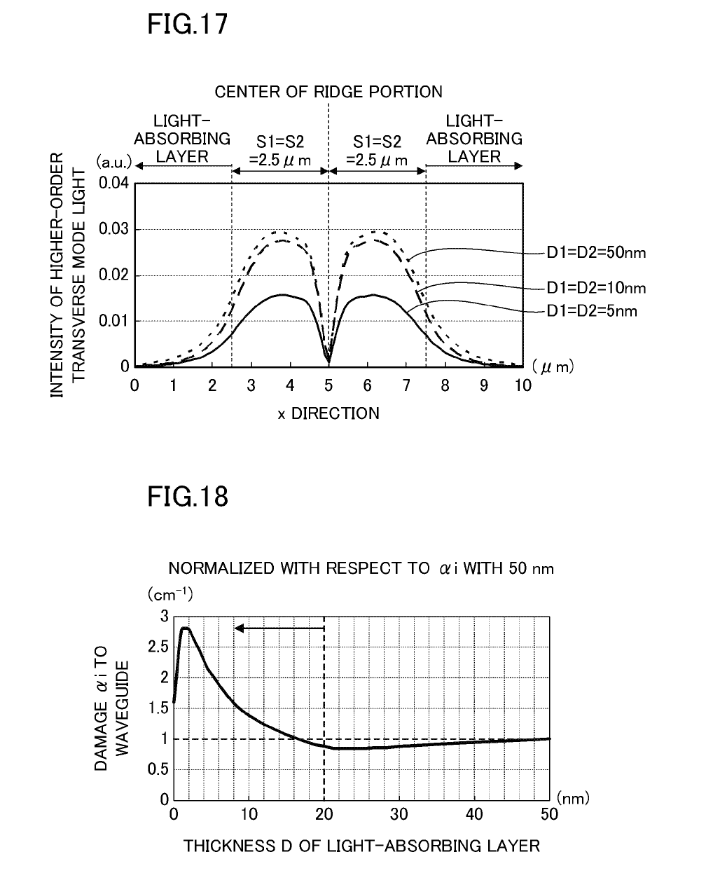

FIG. 17 illustrates the calculation result of the intensity of the higher-order transverse mode light where the thickness D of the light-absorbing layer 59 in the nitride semiconductor laser diode 150 having the structures shown in FIGS. 3, 15, and 16 is uniformly varied (D1=D2) in a longitudinal direction of the cavity (the emitting direction of laser light). In FIG. 17, the distance S from the center of the ridge portion of the ridge portion 56a to the side surface of the light-absorbing layer 59 at the side of the ridge portion 56a is 2.5 μm. FIG. 17 illustrates the calculation result of the intensity of the higher-order transverse mode light, where the thickness D of the light-absorbing layer 59 is 5 nm, 10 nm, and 50 nm.

As shown in FIG. 17, it can be seen that the intensity of the higher-order transverse mode light causing kinks is reduced with a decrease in the thickness D of the light-absorbing layer 59. This is because, due to the decrease in the thickness of the light-absorbing layer 59, the higher-order transverse mode light easily expands to the side of the light-absorbing layer 59 so that the higher-order transverse mode light is effectively absorbed by the light-absorbing layer 59. This makes it difficult to cause the interference between the fundamental transverse mode light and the higher-order transverse mode light so that the nitride semiconductor laser diode 150 stably operates even with high output.

FIG. 18 illustrates a calculation result of a damage αi to a waveguide of the higher-order transverse mode light where the thickness D of the light-absorbing layer 59 is reduced from 50 nm to 0 nm. The figure illustrates the calculation result normalized with respect to the damage αi to the waveguide where the thickness D of the light-absorbing layer 59 is 50 nm. A large damage αi to the waveguide shows that the higher-order transverse mode light is largely absorbed. It can be seen from FIG. 18 that, when the thickness D of the light-absorbing layer 59 is gradually reduced from 50 nm, there are slight differences in the absorption of the higher-order transverse mode light until the thickness D reaches 20 nm. When the thickness D is 20 nm or less, the absorption of the higher-order transverse mode light increases. Furthermore, when the thickness D is gradually reduced to 2 nm, 1 nm, and etc., the maximum higher-order transverse mode light is absorbed. The amount of the absorption is as about 2.8 times as high as that of the higher-order transverse mode light where the thickness is 50 nm. A maximum advantage is expected in the improvement in the kink level.

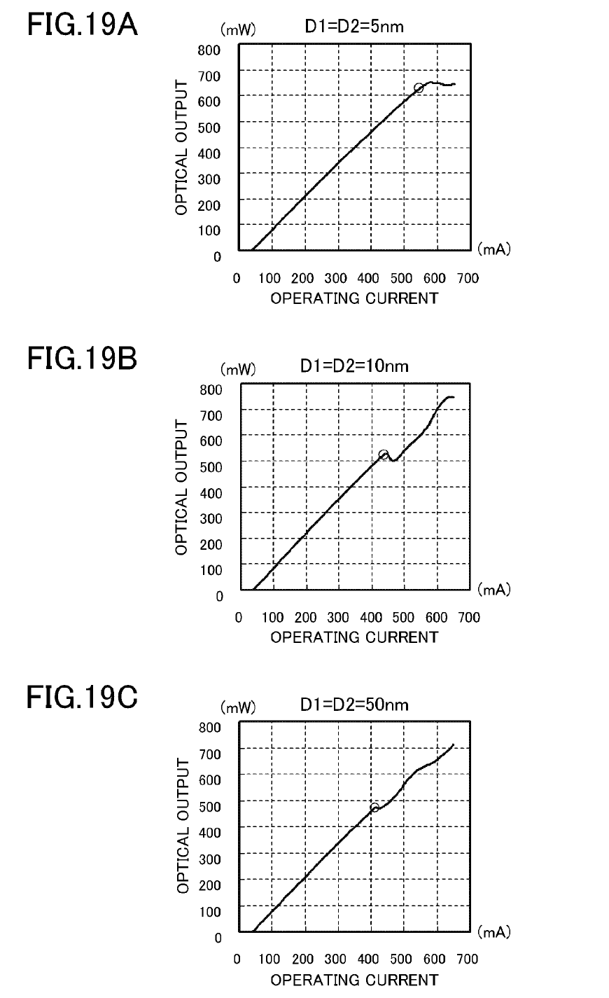

FIGS. 19A-19C illustrate representative operating current-optical output characteristics (hereinafter referred to as “I-L characteristics”) analyzed in samples of the nitride semiconductor laser diode 150, in which the distance S from the center of the ridge portion of the ridge portion 56a to the side surface of the light-absorbing layer 59 at the side of the ridge portion 56a is 25 μm, and the thickness D of the light-absorbing layer 59 is 5 nm, 10 nm, and 50 nm. As shown in FIG. 19C, when the thickness of the light-absorbing layer 59 is 50 nm, the kink level is 470 mW. On the other hand, as shown in FIG. 19A, when the thickness of the light-absorbing layer 59 is 5 nm, the kink level is 620 mW. It can be seen that the kink level can be improved by 150 mW.

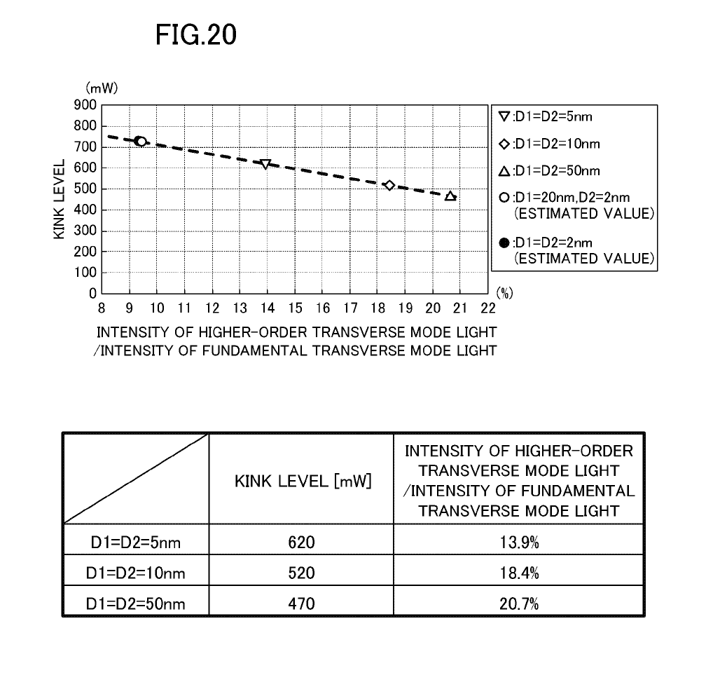

FIG. 20 illustrates the relationship between the percentage of the higher-order transverse mode light in the fundamental transverse mode light corresponding to FIGS. 19A-19C. The result of the percentage of the higher-order transverse mode light in the fundamental transverse mode light is obtained by calculation. The result of the kink level is obtained by analyzing the samples of the nitride semiconductor laser diode 150. It can be seen from FIG. 20 that the percentage of the higher-order transverse mode light in the fundamental transverse mode light is substantially proportional to the kink level. That is, the smaller the percentage of the higher-order transverse mode light in the fundamental transverse mode light is, the higher the kink level becomes. This is because, the interference between the fundamental transverse mode light and the higher-order transverse mode light decreases by reducing the percentage of the higher-order transverse mode light in the fundamental transverse mode light. The samples are analyzed where the thickness D of the light-absorbing layer 29 is up to 5 nm. As shown in Table 1, the kink level can be further improved by reducing the thickness D of the light-absorbing layer 59 to 2 nm.

Table 1 illustrates the results of the percentage of the higher-order transverse mode light in the fundamental transverse mode light where the thickness D of the light-absorbing layer 59 is uniformly reduced to 2 nm, and where the relationship between the thickness D1 of the first region and the thickness d2 of the second region is D1>D2 (where D1=20 nm, and D2=2 nm) as in the third example embodiment.

TABLE 1

| | INTENSITY OF HIGHER-ORDER |
|---|---|
| | TRANSVERSE MODE LIGHT/ |
| | INTENSITY OF FUNDAMENTAL |
| | TRANSVERSE MODE LIGHT |
| D1 = D2 = 2 nm | 9.382% |
| D1 = 20 nm, D2 = 2 nm | 9.384% |

As can be seen from Table 1, when the thickness D of the light-absorbing layer 59 is 2 nm, the percentage of the higher-order transverse mode light in the fundamental transverse mode light is 9.382%. Thus, when estimated from FIG. 20, the kink level is about 720 mW. Therefore, it can be seen that the kink level is largely improved. Also, as shown in the third example embodiment, when the thickness D1 of the first region is 20 nm, and the thickness D2 of the second region is 2 nm, the percentage of the higher-order transverse mode light in the fundamental transverse mode light is 9.384%. Therefore, it can be seen that similar advantages to those in the case, where the thickness of the light-absorbing layer 59 is uniformly reduced, can be obtained.

As such, the thickness D of the light-absorbing layer 59 is reduced to effectively absorb the higher-order transverse mode light, thereby reducing the interference between the fundamental transverse mode light and the higher-order transverse mode light. As a result, the nitride semiconductor laser diode 150 can operate even with high output without causing any kink.

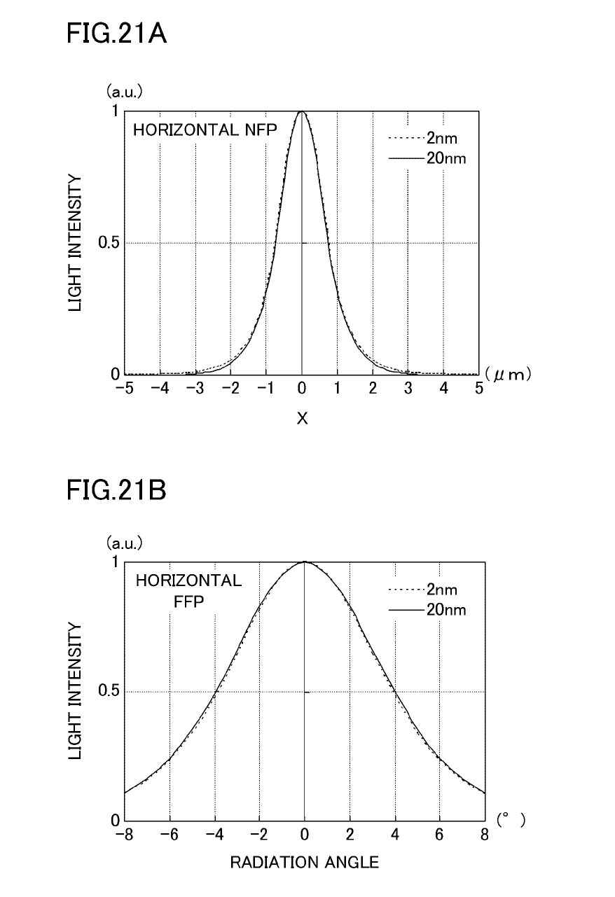

FIGS. 21A and 21B illustrate calculation results of a horizontal NFP and a horizontal FFP in the nitride semiconductor laser diode 150, which is shown in FIGS. 3, 15, 16 and includes the first region and the second region in the light-absorbing layer 59. In FIGS. 21A and 21B, solid lines represent the horizontal NFP and the horizontal FFP of the first region where the thickness D1 of the light-absorbing layer 59 is 20 nm. Dashed lines represent the horizontal NFP and the horizontal FFP of the first region where the thickness D1 of the light-absorbing layer 59 is 2 nm. The horizontal NFP is represented by a beam radius X (μm), and the horizontal FFP is represented by a radiation angle(°).

Table 2 illustrates calculated values of the horizontal FFPs where the relative intensity ratio of laser light is 0.5 in the first region and the second region of the light-absorbing layer 59.

TABLE 2

| | FIRST REGION | SECOND REGION |
|---|---|---|
| | D1 = 20 nm | D2 = 2 nm |
| HORIZONTAL FFP | 7.98° | 7.71° |

As shown in Table 2, the horizontal FFP in the first region is 7.98°, and the horizontal FFP in the second region is 7.71°. Therefore, the horizontal FFP is narrow in the second region in which the thickness D of the light-absorbing layer 59 is small. That is, stable high-output operation can be obtained by reducing the thickness D of the light-absorbing layer 59 to narrow the horizontal FFP. This is because it is difficult to absorb the foot of the fundamental transverse mode light, which leaks outside the ridge portion 56a due to the light-absorbing layer 59. Thus, by increasing the thickness D1 of the first region of the light-absorbing layer 59 at the side of the front facet 65, a decrease in the horizontal FFP can be mitigated.

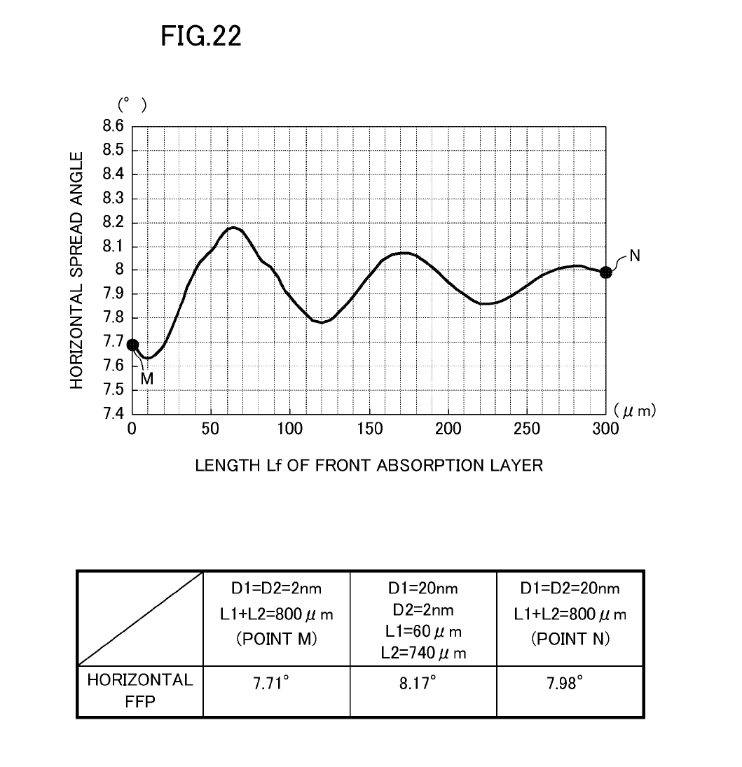

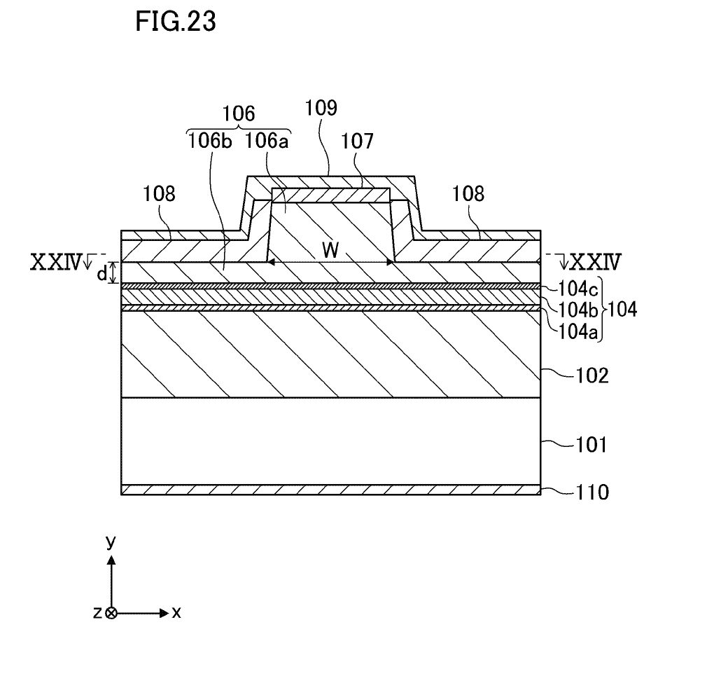

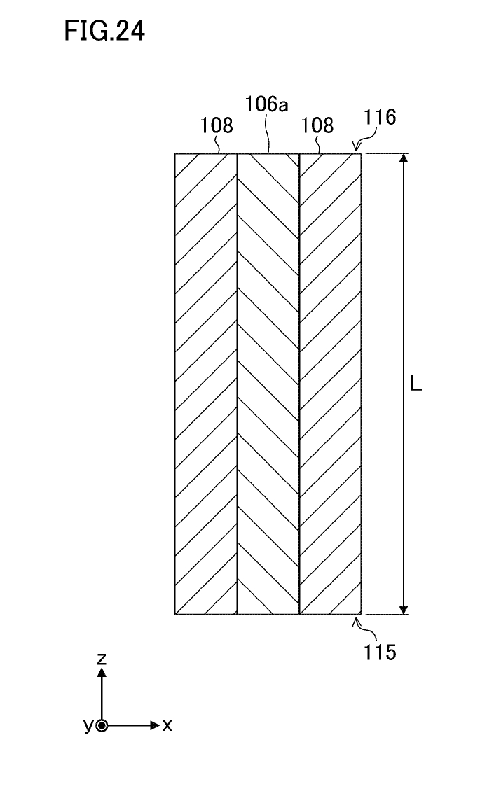

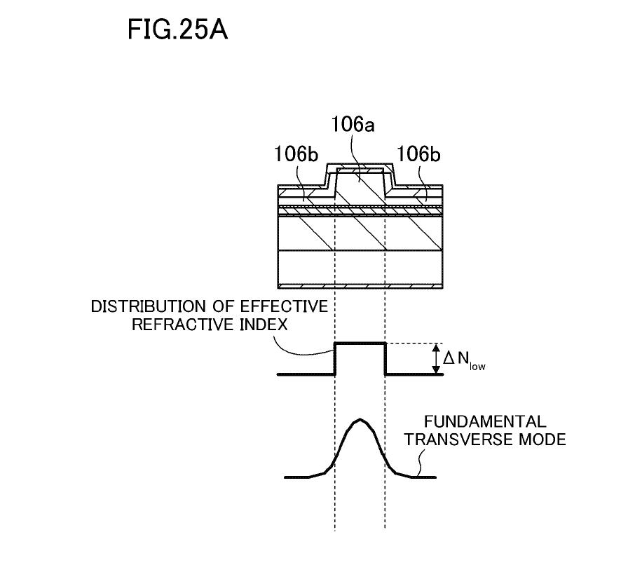

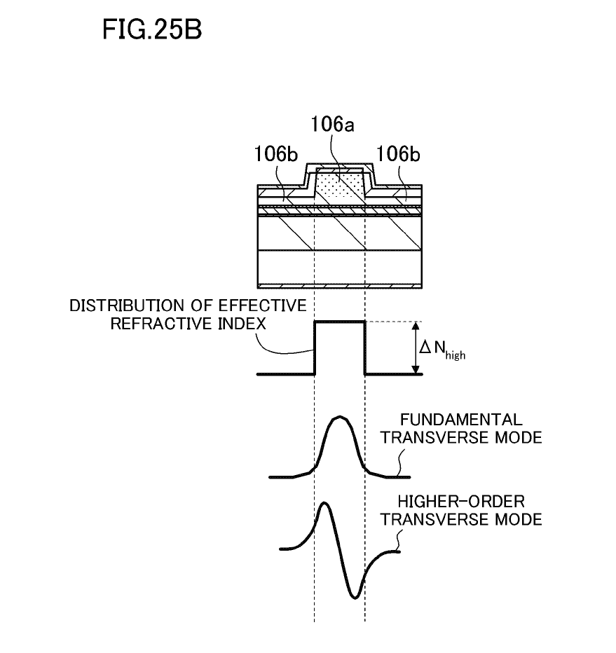

FIG. 22 illustrates a calculation result of the horizontal FFP in the nitride semiconductor laser diode 150 shown in FIGS. 3, 15, and 16, where the length L1 of the first region in the light-absorbing layer 59 is changed from 0 μm to 300 μm. Point M in FIG. 22 shows the calculation result of the horizontal FFP where L1=0, i.e., there is no first region, and the second region is located in the region from the front facet 65 to the rear facet 66. Furthermore, point N shows the calculation result of the horizontal FFP where L1=300, i.e., the first region is the region being 300 μm from the front facet 65.

It can be seen from FIG. 22 that the horizontal FFP fluctuates with a change in the length L1 of the first region of the light-absorbing layer 59, and converges to 7.98°, which is the horizontal FFP in a stationary state of the first region while fluctuating, when the length L1 is about 260 μm.

When the length L1 of the first region of the light-absorbing layer 59 is 100 μm or less, the horizontal FFP fluctuates at an angle wider than 7.98° which is the convergence point of the horizontal FFP in the first region. The calculation result shows that the maximum value of the horizontal FFP is 8.17° where the length L1 is 60 μm. This it the phenomenon caused by a mode mismatch between the shapes of the fundamental transverse mode light in the first region (hereinafter referred to as “first fundamental transverse mode light”) and fundamental transverse mode light in the second region (hereinafter referred to as “second fundamental transverse mode light”).

When the second fundamental transverse mode light in the second region propagating from the direction of the rear facet 66 propagates to the boundary with the first region, the mode mismatch with the first fundamental transverse mode light in the first region causes interference at the boundary between the first region and the second region. Then the second fundamental transverse mode light passes through the first region while oscillating so that the mode of the light converges to the first fundamental transverse mode light, and reaches the front facet 65. Thus, in the region near the boundary between the first region and the second region, i.e., in the region in which the L1 is short, the mode mismatch between the first fundamental transverse mode light and the second fundamental transverse mode light is large, the fundamental mode light propagates while rapidly oscillating. At this time, the component of this mode mismatch is radiated outside the ridge portion 56a in the radiation mode in the process in which the fundamental transverse mode light is changed from the second fundamental transverse mode light to the first fundamental transverse mode light. The most part of the component is absorbed by the light-absorbing layer 59.

As such, in order to obtain satisfactory high-output characteristics in the nitride semiconductor laser diode 150, the thickness of the second region of the light-absorbing layer is reduced, and the length L1 of the first region of the light-absorbing layer 59 is controlled, thereby actively using the interference of the fundamental transverse mode light with the second region. This makes the value of the horizontal FFP in the first region larger than the value of the horizontal FFP in the second region.

Furthermore, according to the third example embodiment, an increase in the angle of the horizontal FFP can damage light effectively utilized in an optical pickup lens to set optical output high in reproduction. Thus, deterioration of noise characteristics in the reproduction of optical disks can be reduced. In particular, such an advantages is significant in a nitride semiconductor laser diode having specific noise.

Note that, the thickness D2 of the second region of the light-absorbing layer 59 needs to range from 2 nm to 20 nm. This is because, when the thickness D2 of the second region in the light-absorbing layer 59 is less than 2 nm, it is difficult to stably deposit the light-absorbing layer 59. Also, when the thickness D2 of the second region in the light-absorbing layer 59 is more than 20 nm, the percentage of the higher-order transverse mode light in the fundamental transverse mode light increases. As a result, a desirable kink level cannot be obtained.

The thickness D1 of the first region in the light-absorbing layer 59 needs to range from 2 nm to 50 nm. At this time, clearly, the thickness D1 of the first region and the thickness D2 of the second region in the light-absorbing layer 59 needs to satisfy the expression D1>D2. This is because, when the thickness D1 of the first region in the light-absorbing layer 59 is less than 2 nm, it is difficult to stably deposit the light-absorbing layer 59 as described above. Also, when the thickness D2 of the second region in the light-absorbing layer 59 is more than 50 nm, the light-absorbing layer 59 may be easily destroyed so that the insulating film 58 may be removed at the boundary between the insulating film 58 and the light-absorbing layer 59 to cause damages such as current leakage and deterioration of the processability. When the thickness D1 of the first region in the light-absorbing layer 59 ranges from 2 nm to 50 nm, the mode mismatch of the fundamental transverse mode light at the boundary between the first region and the second region can be increased in the condition satisfying the expression D1>D2, thereby increasing the angle of the horizontal FFP.

In the nitride semiconductor laser diode 150 according to the third example embodiment, where S1 in the first region is the distance from the center of the ridge portion, which is parallel to the emitting direction of laser light and is a line-symmetric axis of the ridge portion 56a, to the side surface of the light-absorbing layer 59 at the side of the ridge portion 56a; and S2 is the distance in the second region from the center of the ridge portion to the side surface of the light-absorbing layer 59 at the side of the ridge portion 56a, the relationship between the distance S1 and the distance S2 is represented by S≦S2.

Then, the interference of the fundamental transverse mode light between the first region and the second region can be actively utilized, thereby making the value of the horizontal FFP in the first region larger than the value of the horizontal FFP of the second region to increase the angle. As a result, the nitride semiconductor laser diode 150 with emitted beam having a stable radiation angle, i.e., stable FFP characteristics, can be realized.

The distance S1 in the first region from the center of the ridge portion to the side surface of the light-absorbing layer 59 at the side of the ridge portion 56a is preferably 1.0 μm or more, and the distance S2 in the second region from the center of the ridge portion to the side surface of the light-absorbing layer 59 at the side of the ridge portion 56a preferably ranges from 1.0 μm to 2.5 μm. At this time, the relationship between S1 and S2 preferably satisfies the above-described expression of S1 ≦S2. When the distances S1 and S2 are less than 1 μm, the fundamental transverse mode light of the nitride semiconductor laser diode 150 is absorbed by the light-absorbing layer 59 to increase the threshold current and reduce slope efficiency. In addition, heat generation with the light-absorbing layer 59 serving as an absorbing body damages the long-term reliability. When the distance S2 is more than 2.5 μm, the mode mismatch of the fundamental transverse mode light at the boundary between the first region and the second region decreases to reduce the amount of change in the horizontal FFP.

In the semiconductor laser diode 150 according to the third example embodiment, the Al composition, the In composition, and the thickness of each of the nitride semiconductor layers are set as examples as shown in FIG. 3, but are not limited thereto. The values can be also changed, when the maximum optical output and the design of the FFP of the nitride semiconductor laser diode is changed.

The length L1 of the first region in the light-absorbing layer 59 in a longitudinal direction of the cavity is preferably set within a range from 20 μm to 150 μm. This is because the amount of an increase in the horizontal FFP is small where the length L1 is less than 20 μm. Where the length L1 is more than 150 μm, the amount of change in the horizontal FFP decreases and the absorption of the fundamental transverse mode light increases to damage laser characteristics such as a decrease in the kink level.

The length L2 of the second region in the light-absorbing layer 59 in the longitudinal direction of the cavity reduces distortion of the waveform of the horizontal NFP due to stray light, even if the sum of L1 and L2 is not equal to the cavity length.

The width Ws of the light-absorbing layer 59 is set within a range from 4 μm to 20 μm. When the width Ws is less than 4 μm, the absorption of light leaking outside the ridge portion 56a becomes weak, thereby causing ripples to distort the FFP waveform. When the width Ws is more than 20 μm and the light-absorbing layer 59 is made of α-Si and the like, the adhesiveness between the light-absorbing layer 59 and the insulating film 58 is decreased to deteriorate processability of the nitride semiconductor laser diode 150, thereby reducing the yield of the assembly process.

The width W of the ridge portion 56a is preferably set in a range from 1.1 μm to 1.7 μm. This is because, where the ridge width W is less than 1.1 μm, the series resistance increases in the nitride semiconductor laser diode 150 to increase the operating voltage. Where the ridge width W is more than 1.7 μm, the guided mode condition in the nitride semiconductor laser diode 150 does not satisfy the single mode condition, thereby causing higher-order transverse mode light to lower the kink level.

As described above, in the nitride semiconductor laser diode 150 according to the third example embodiment, the thickness D1 of the first region of the light-absorbing layer 59 at the side of the front facet 65 is larger than the thickness D2 of the second region other than the first region. Such the nitride semiconductor laser diode 150 enables high-output operation to be stabilized, and the angle of the horizontal FFP to increase; and is thus preferable as a light source for Blu-ray Discs.

The first to third example embodiments are not limited to the above-described structures, and various modifications and variations can be made thereto, falling within the scope of the invention.

For example, the materials of the nitride semiconductor layers are not limited to AlₓGa₁₋ₓN and In_{y}Ga_{1-y}N, and may be other nitride semiconductor materials. Furthermore, other materials may be used for the light-absorbing layer, depending on the type of the semiconductor materials.

Furthermore, the lengths, width, and thickness of the light-absorbing layer, the width of the ridge portion, etc. may be changed as appropriate.

As described above, according to the present disclosure, a semiconductor laser diode having stable far field pattern (FFP) characteristics and an increased angle can be realized even when laser light has high output power. Therefore, the semiconductor laser diode according to the present disclosure is used as a nitride semiconductor laser diode suited for an optical disk system for Blu-rays.

What is claimed is:

1. A nitride semiconductor laser diode, comprising:
a first conductive cladding layer formed on a substrate;
an active layer formed on the first conductive cladding layer;
a second conductive cladding layer formed on the active layer, and including a ridge portion extending in an emitting direction of light and having a raised cross-sectional shape, and flat portions located on both sides of the ridge portion;
a light-absorbing layer formed on each of the flat portions, and having an optical absorption coefficient larger than the second conductive cladding layer with respect to an oscillation wavelength; and
an insulating film formed on side surfaces of the flat portions and the ridge portion of the second conductive cladding layer including the light-absorbing layer, wherein
the light-absorbing layer includes
a first region provided at a side of a light-emitting facet, and having a distance Di1 from a center of the ridge portion, which is a line-symmetric axis in a longitudinal direction of the ridge portion, to a side surface of the light-absorbing layer at a side of the ridge portion, and
a second region provided at a side opposite to the light-emitting facet to be continuous with or spaced apart from the first region, and having a distance Di2 from the center of the ridge portion to the side surface of the light-absorbing layer at the side of the ridge portion, and
a relationship between the Di1 and the Di2 is represented by Di1<Di2.

2. The nitride semiconductor laser diode of claim 1, wherein
the distance Di1 continuously changes to the distance Di2 in the second region.

3. The nitride semiconductor laser diode of claim 1, wherein
the light-absorbing layer is made of a material absorbing laser light with a wavelength of 405 nm band.

4. The nitride semiconductor laser diode of claim 3, wherein
the light-absorbing layer is made of silicon or amorphous silicon.

5. The nitride semiconductor laser diode of claim 1, wherein
the light-absorbing layer absorbs laser light having a beam radius out of a predetermined range of size in the first region.

6. The nitride semiconductor laser diode of claim 1, wherein
the second conductive cladding layer has a thickness ranging from 10 nm to 70 nm at the flat portions.

7. The nitride semiconductor laser diode of claim 1, wherein
the Di1 ranges from 1.0 μm to 2.0 μm.

8. The nitride semiconductor laser diode of claim 1, wherein
the Di2 is 2.5 μm or more.

9. The nitride semiconductor laser diode of claim 1, wherein
the first region in the light-absorbing layer has a length ranging from 10 μm to 100 μm in the emitting direction of the light.

10. The nitride semiconductor laser diode of claim 1, wherein
the second region in the light-absorbing layer has a length of 30 μm or more in the emitting direction of the light.

11. The nitride semiconductor laser diode of claim 1, wherein
the first region in the light-absorbing layer has a width ranging from 4 μm to 25 μm.

12. The nitride semiconductor laser diode of claim 1, wherein
the first region in the light-absorbing layer has a thickness ranging from 20 nm to 140 nm.

13. The nitride semiconductor laser diode of claim 1, wherein
where the second region is spaced apart from the first region, the space between the first region and the second region is 10 μm or less.

14. The nitride semiconductor laser diode of claim 1, wherein
the ridge portion has a width ranging from 1.1 μm to 1.7 μm.

15. The nitride semiconductor laser diode of claim 1, wherein
the substrate is made of n-type gallium nitride,
the first conductive cladding layer is made of n-type nitride semiconductor,
the second conductive cladding layer is made of p-type nitride semiconductor, and
the active layer is made of nitride semiconductor.

16. A nitride semiconductor laser diode, comprising:
a first conductive cladding layer formed on a substrate;
an active layer formed on the first conductive cladding layer;
a second conductive cladding layer formed on the active layer, and including a ridge portion extending in an emitting direction of light and having a raised cross-sectional shape, and flat portions located on both sides of the ridge portion;
a light-absorbing layer formed above each of the flat portions with a space interposed therebetween, and having an optical absorption coefficient larger than the second conductive cladding layer with respect to an oscillation wavelength; and
an insulating film formed on side surfaces of the flat portions and the ridge portion of the second conductive cladding layer including the light-absorbing layer, wherein
the light-absorbing layer includes
a first region provided at a side of a light-emitting facet and having a thickness D1, and
a second region connected to the first region and having a thickness D2, and
a relationship between the D1 and the D2 is represented by D1<D2.

17. The nitride semiconductor laser diode of claim 16, wherein
the light-absorbing layer is made of a material absorbing laser light with a wavelength of 405 nm band.

18. The nitride semiconductor laser diode of claim 17, wherein
the light-absorbing layer is made of silicon or amorphous silicon.

19. The nitride semiconductor laser diode of claim 16, wherein
the light-absorbing layer has a thickness D2 ranging from 2 nm to 20 nm in the second region.

20. The nitride semiconductor laser diode of claim 16, wherein
the light-absorbing layer has a thickness D1 ranging from 2 nm to 50 nm in the first region.

21. The nitride semiconductor laser diode of claim 16, wherein
where S1 is a distance in the first region from a center of the ridge portion, which is a line-symmetric axis in a longitudinal direction of the ridge portion, to a side surface of the light-absorbing layer at a side of the ridge portion; and S2 is a distance in the second region from the center of the ridge portion to the side surface of the light-absorbing layer at the side of the ridge portion,
a relationship between the S1 and the S2 is represented by S1≦S2.

22. The nitride semiconductor laser diode of claim 21, wherein
the distance S1 in the first region is 1.0 μm or more.

23. The nitride semiconductor laser diode of claim 21, wherein
the distance S2 in the second region ranges from 1.0 μm to 2.5 μm.

24. The nitride semiconductor laser diode of claim 16, wherein
where L1 is a length of the first region in the light-absorbing layer in the longitudinal direction of the ridge portion,
the L1 ranges from 20 μm to 150 μm.

25. The nitride semiconductor laser diode of claim 24, wherein
where L2 is a length of the second region in the light-absorbing layer in the longitudinal direction of the ridge portion,
a sum of the L1 and the L2 is equal to or less than a length of the ridge portion in the longitudinal direction.

26. The nitride semiconductor laser diode of claim 16, wherein
a width of the light-absorbing layer in a direction perpendicular to a longitudinal direction of the ridge portion ranges from 4 μm to 20 μm.

27. The nitride semiconductor laser diode of claim 16, wherein
a width of the ridge portion ranges from 1.1 μm to 1.7 μm.

28. The nitride semiconductor laser diode of claim 16, wherein
the substrate is made of n-type gallium nitride,
the first conductive cladding layer is made of n-type nitride semiconductor,
the second conductive cladding layer is made of p-type nitride semiconductor, and
the active layer is made of nitride semiconductor.
